(19) United States
(12) Patent Application Publication
(10) Pub. No.: US 2011/0104840 A1
(43) Pub. Date: May 5, 2011

(54) Etchant Solutions And Additives Therefor

(75) Inventors: Dirk Burdinski, Eindhoven (NL); Harold Brans, Eindhoven (NL)

(73) Assignee: KONINKLIJKE PHILIPS ELECTRONICS, N.V., EINDHOVEN (NL)

(21) Appl. No.: 11/720,524

(22) PCT Filed: Nov. 30, 2005
(86) PCT No.: PCT/IB2005/053989

§ 371 Date: Mar. 24, 2009

(30) Foreign Application Priority Data
Dec. 6, 2004 (EP) 04106303.3
Mar. 18, 2005 (EP) 05102155.8

(51) Int. Cl. H01L 33/00; C23F 1/00; C09K 13/06; C09K 13/08

(52) U.S. Cl. 438/34; 216/41; 216/43; 252/79.4; 252/79.3; 257/E33.001

(57) ABSTRACT

The present invention is concerned with etchant or etching solutions and additives therefor, a process of preparing the same, a process of patterning a substrate employing the same, a patterned substrate thus prepared in accordance with the present invention and an electronic device including such a patterned substrate. An etchant solution according to the present invention for patterned etching of at least one surface or surface coating of a substrate comprises nitric acid, a nitrite salt, a halogenated organic acid represented by the formula C(H)n(Hal)m[C(H)o(Hal)p]qCθ2H, where Hal represents bromo, chloro, fluoro or b iodo, where n is 0, 1, 2 or 3, and m is 0, 1, 2 or 3, with the proviso that m+n=3; o is 0 or 1, p is 1 or 2, with the proviso that o+p=2; q is 0 or 1, with the proviso that q+m=1, 2, 3 or 4; and balance water.

The present invention is concerned with etchant or etching solutions and additives therefor, a process of preparing the same, a process of patterning a substrate employing the same and a patterned substrate thus prepared in accordance with the present invention.

Patterning a metal, metal oxide or other material over a substrate is a common need and important process in modern technology, and is applied, for example, in microelectronics and display manufacturing. Metal patterning usually requires the homogeneous deposition of a material over the entire surface of a substrate and its selective removal using a combination of photolithography and etching techniques. Cheap and large area patterning technology is of utmost importance for the development of future large area display and plastic electronics technologies.

Microcontact printing (μCP) is a soft lithographic patterning technique that has the inherent potential for the easy, fast and cheap reproduction of structured surfaces and electronic circuits with medium to high resolution (feature size currently ≧100 nm) even on curved substrates. It offers experimental simplicity and flexibility in forming various types of patterns by printing molecules from a stamp onto a substrate.

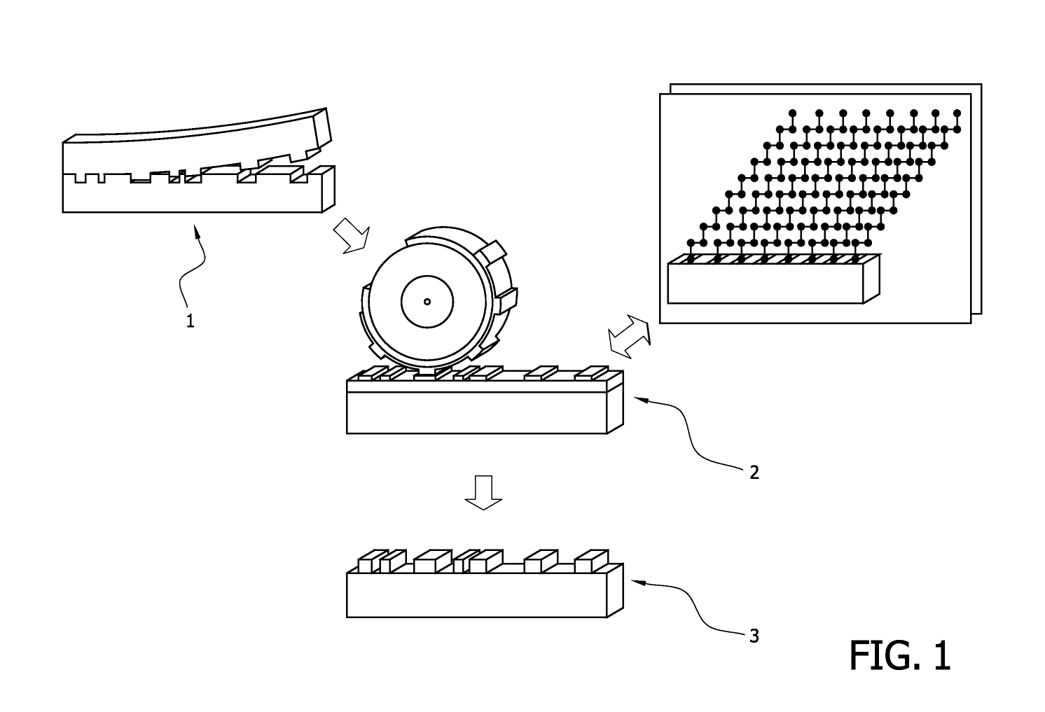

The four key steps of a microcontact process are (with reference to FIG. 1 of the drawings):

Reproduction of a stamp (1) with the desired pattern;

Loading of the stamp (1) with an appropriate ink solution;

Printing with the inked and dried stamp (1) to transfer the pattern from the stamp (1) to the surface (2); and

Development (fixation) of the pattern by means of chemical or electrochemical processes.

Printing of higher alkanethiols as ink molecules onto gold was the first μCP technique developed (A. Kumar and G. M. Whitesides, Formation of microstamped patterns on surfaces and derivative article, U.S. Pat. No. 5,512,131; A. Kumar, II. A. Biebuyck, N. L. Abbott and G. M. Whitesides, The Use of Self Assembled Monolayers and a Selective Etch to Generate Patterned Gold Features. Journal of American Chemical Society, 114, 9188-9 (1992); and A. Kumar and G. M. Whitesides, Features of Gold having micrometer to centimeter dimensions can be formed through a combination of stamping with an elastomeric stamp and an alkanethiol ink followed by chemical etching. Applied Physics Letters, 63, 2002-4 (1993)). These amphipathic thiol molecules form a self assembled monolayer (SAM) of deprotonated thiolates on the surface resembling the pattern of the stamp. The driving force for the formation of the SAM is the strong interaction of the polar thiolate head groups with the gold atoms (or atoms of other metals) in the uppermost surface layer, on the one hand, and the intermolecular (hydrophobic) van der Waals interaction between the apolar tail groups in the SAM, on the other hand. The combination of these two interactions results in a well ordered SAM of high stability against mechanical, physical or chemical attack. Besides the described example, other types of inks or materials may be employed to create a patterned layer on a substrate surface via microcontact printing. The so generated patterned layer may be used as an etch resist similar to development processes in conventional (photo-) lithographic processes. The suitability of such layers as an etch resist strongly depends on its molecular composition and on the type of etching bath used.

The development of microcontact printed patterns in gold and silver, as well as alloys based on any of these metals, by wet chemical etching is of utmost importance, especially for applications in large area electronics and display applications. Although there are various etching baths available that are suitable in combination with μCP on a laboratory scale, they have certain drawbacks, such as low stability, high toxicity or a poor selectivity that may hamper their applicability in large scale production processes. A particular problem is the development of microcontact printed substrates composed of more than one metal layer to be patterned. Silicon or glass substrates usually require an adhesion layer to assure an indispensable sufficiently high adhesion of gold and silver layers to the substrate. These adhesion layers are, for instance, a few to some tens of nanometers thick layers of molybdenum, titanium, or chromium or alloys thereof. For the development of such multi-layer substrates usually a different etching bath is required for each individual metal layer. The complete removal of all metal layers is essential to assure electric insulation of the individual electronic components. For instance, substrates of gold on silicon wafers, bearing a titanium adhesion layer are usually developed by first etching the gold layer using a strongly alkaline to neutral cyanide-, thiosulphate-, or thiourea-based etching bath followed by etching the titanium layer with a strongly oxidizing acidic etching bath. Each etching procedure (which itself usually consists of several steps) of such multi-step development procedures causes significant physical and chemical stress to the etch resist and consequently reduces the achievable quality and resolution of the patterning process. Moreover the resist has to be stable against as different conditions as strongly oxidizing, very acidic and basic etching solutions. All these problems become increasingly important for very sensitive etching resists, such as those used in μCP.

Substrates and in particular glass substrates with an especially important material combination are those bearing a layer of silver or an alloy thereof on an adhesion layer of molybdenum or an alloy thereof. They are envisaged as the basis for the driver electronics of future generation (printable) AM-LCD display and in particular TV designs.

The development of microcontact printed silver substrates by wet chemical etching has been reported. The used etching solutions are similar to those used for the etching of respective gold substrates. Due to the fact that silver is less noble than gold, thus it is easier to oxidize, usually higher etching rates are observed for silver compared to gold. The described etching solutions are generally neutral or moderately alkaline or acidic aqueous solutions containing a coordinating ion (a ligand) selected to reduce the redox potential of the metal and an oxidizing agent with a sufficiently high redox potential to cause oxidation of the metal in the presence of the ligand. Examples of often used ligands are cyanide, thiosulphate or thiourea.

The development of patterns in molybdenum or alloys thereof are usually based on acidic etching baths, due to the formation of passivating layers of molybdenum oxides or polymolybdates in moderately alkaline solutions. However, strongly alkaline baths containing oxidants such as ferricyanide or hydrogen peroxide and additional weak coordinating ions, such as oxalate, are sometimes employed as well. The use of etching baths in combination with μCP has not, however, previously been employed for molybdenum patterning.

There is a need for a cheap, large area patterning of the conductive layers in the driver electronics of AM-LCD displays and TV systems. In a key step, substrates with the following structure need to be patterned for the definition of the gate electrode layer of such electronic circuits, namely a glass substrate with a molybdenum or preferably a molybdenum—chromium adhesion layer (97% Mo, 3% Cr, Mo(Cr); thickness 20 nm, sputtered) and a layer of silver alloy (98.1% Ag, 0.9% Pd, 1.0% Cu; APC; thickness 200 nm, sputtered).

Microcontact printing of alkanethiol SAMs on gold in particular and also silver is a well established procedure for the patterning of layers of those materials down to a resolution of micron or even submicron feature sizes on small substrates. Controlled microcontact printing on large areas has recently become possible in view of the recently developed wave printing technology, as described in WO 03/099463.

The patterning of silver alloys, molybdenum or molybdenum alloys with μCP has, however, not hitherto been demonstrated in view of the following considerations.

The etching of silver alloys, such as APC, is more demanding than the etching of pure silver layers.

The etch stability of SAM resists on silver alloys, such as APC, has never been investigated and is, therefore, unknown.

The known neutral or alkaline etching baths that have been used for the etching of microcontact printed silver layers do not etch molybdenum at any sufficient rate.

For the etching of molybdenum, preferably acidic etching solutions are used, due to the possible formation of passivating oxide or polymolybdate layers in moderately alkaline etching baths.

Etching of molybdenum-chromium alloys is more demanding than the etching of pure molybdenum.

The use of acidic etching solutions has rarely been reported in combination with microcontact printed etch resists.

Known basic and acidic etching solutions for molybdenum also etch silver at a comparable or even higher rate, so that no simple selective two step etching procedure has hitherto been envisaged.

With etching baths known from other technologies, such as photolithography, no sufficient selectivity can be achieved, and additionally no sufficiently reproducible and homogeneous etching can be achieved.

Thus an etching bath is required to etch both metal layers of microcontact printed substrates of the described composition homogeneously over substrates with a diameter of about or more than six inches with a high selectivity and resolution. The described problem is only one example of the general problem of etching multi-layer substrates composed of silver and molybdenum alloy layers in a one step procedure.

In the context of the prior art relating to silver etching, Xia et al (Y. Xia, E. Kim and G. M. Whitesides, Microcontact printing of Alkanethiols on Silver and its Application in Microfabrication, Journal of the Electrochemical Society, 143, 1070-9 (1996)) reported a systematic study on microcontact printing on silver and producing silver micro- and nano-structures therewith via wet chemical etching. The suitability of a variety of potential etching baths was examined. The results are summarized in following Table 1, which details solutions examined for use with patterned SAMs of hexadecanethiol on 50 nm silver layers.

TABLE 1

| | Coordinating | | |
|---|---|---|---|
| Oxidant^{a} | Ligand^{a} | Etching Rate^{b} | Selectivity^{c} |
| K₃Fe(CN)₆(0.01) | None | − | −− |
| | K₂S₂O₃ (0.1) | ++ | ++ |
| | NH₄OH (8.2) | ++ | + |
| | NH₄OH (0.16) | + | + |
| | KSCN (0.1) | + | + |
| | KCl (0.1) | + | + |
| | KBr (0.1) | + | + |
| | KI (0.1) | + | + |
| Fe(NO₃)₃ (0.05) | None | ++ | ++ |
| O₂ (saturated) | KCN (0.01) | + | ++ |
| | NH₄OH (8.2) | + | + |
| | H₂NCH₂COOH | − | −− |
| | (0.1) | | |
| | KSCN (0.01) | − | −− |
| | K₂S₂O₃ (0.01) | − | −− |
| H₂O₂ (0.17) | NH₄OH (0.16) | + | + |
| | H₂NCH₂COOH | + | + |
| | (0.1) | | |
| FeCl₃ (0.01) | KCl (0.1) | 0 | − |
| | KI (0.1) | + | − |
| I₂ (0.005) | KI (0.1) | ++ | − |

^{a}(Concentration, M)
^{b}All etchings were carried out at room temperature
++ = very rapid (100 to 300 nm/s)
+ = rapid (10 to 100 nm/s)
0 = slow (<10 nm/s)
− = very slow (almost no etching)
^{c}key: ++ = excellent, + = good, 0 = fair, − = poor, −− = not examined because the etching was too slow. The evaluation of selectivity was based on the density of defects (using SEM) produced in the SAM covered regions after the underivatized regions of silver just completely (or close to) dissolved.

Etching solutions based on thiosulphate/ferricyanide-, cyanide-, or ferrinitrate generally show a very good silver etching performance. Etching baths employing halogenides of pseudo-halogenides as the ligand are less suited, probably due to the formation of precipitates of silver-ligand complexes with a low solubility in water. All investigated etching solutions work in the alkaline or neutral pH range, which is not suitable for the etching of MoCr. Based on the described results a thiosulphate/ferricyanide etching bath has been used as the preferred etching bath for microcontact printed pure silver substrates (Y. Xia, N. Venkateswaran, D. Qin, J. Tien, and G. M. Whitesides, Use of Electroless Silver as the substrate in microcontact printing of alkanethiols and its application in microfabrication. Langmuir, 14, 363-71 (1998); J. Tate et al., Anodization and Microcontact Printing on Electroless silver: Solution Based fabrication Procedures for low voltage Electronic Systems with Organic Active Components. Langmuir, 16, 6054-60 (2000)).

Other reports discuss the dissolution of silver in etching baths based on thiourea/ferrisulphate (B. Pesic and T. Seal, A Rotating Disk Study of Silver Dissolution with Thiourea in the presence of Ferric Sulphate. Metallurgical Transactions B. Process Metallurgy, 21, 419-27 (1990)) or in ammoniacal solution with cupric ammine (Y. Guan and K. N. Han, The Dissolution Behaviour of Silver in Ammoniacal Solutions with Cupric Ammine. Journal of Electrochemical Society, 141, 91-6 (1994); Y. Guan and K. N. Han, The Dissolution Behaviour of Silver/Copper Alloys in Ammoniacal Solutions. Minerals and Metallurgical Processing, 11, 12-9 (1994)) in the absence of any patterning resist.

With no reference to any patterning technique the use of dilute nitric acid solutions has been reported to roughen the surface of silver foils by etching them for a short period of time (G. Xue and J. Dong, Stable Silver Substrate Prepared by the Nitric Acid Etching Method for a Surface Enhanced Raman Scattering Study. Analytical Chemistry, 63, 2393-7 (1991); R. Perez, A. Ruperez, E. Rodiguez-Castellon and J. J. Laserna, Study of Experimental Parameters for improved adsorbate detectability in SERS using etched silver substrates. Surface and Interface Analysis, 30, 592-6 (2000)).

With respect to prior art techniques relating to molybdenum etching, a selective etching system for molybdenum in combination with the use of microcontact printing as a patterning technique, and thus in combination with the use of self assembled monolayers as the etch resist, has not previously been envisaged.

U.S. Pat. No. 3,639,185 and U.S. Pat. No. 3,773,670 describe a composition for etching thin films of metal, such as chromium or molybdenum, comprising alkaline metal salts of weak inorganic acids which yield solutions having a pH in the range of 12 to 13.5, e.g. alkali meta- or orthosilicates or sodium orthophosphate, and oxidizing agents active in alkaline solutions, such as potassium permanganate or sodium ferricyanide. These documents further describe a method of selectively etching away portions of such metal films by masking the films with positive alkali developed photo resists and treating them with etching solutions as described above.

U.S. Pat. No. 4,212,907 describes a method for etching a molybdenum or molybdenum rich alloy surface to promote the formation of an adherent bond with a subsequently deposited metallic plating. The pre-treatment comprises expositing the crystal boundaries of the surface by (a) anodizing the surface in acidic solution to form a continuous film of grey molybdenum oxide thereon and (b) removing the film.

U.S. Pat. No. 4,780,176 claims a method of cleaning and etching molybdenum, which comprises treating molybdenum in a solution of 2-propanol and H₂O₂.

U.S. Pat. No. 4,747,907 describes a metal etching process involving an oxidation-reduction reaction where the metal being etched is oxidized and the active ingredient in the etching solution is reduced, the active ingredient being selected from the group consisting of ferric ions, ferricyanide ions, ceric ions, chromate ions, dichromate ions, and iodine and introducing ozone into said etching solution to rejuvenate and agitate the solution. Metals being etched in the given examples comprise nickel, molybdenum, chromium and gold.

U.S. Pat. No. 4,995,942 proposes a solution for the problem of the formation of passivating layers of polymolybdates or polytungstates during the etching of molybdenum or tungsten in neutral ferricyanide solutions. The proposed solution comprises the addition of a soluble molybdate or tungstate and an essential compound such that upon combination of said soluble molybdate or tungstate and said essential compound, a heteropoly compound is formed in which said essential compound contributes at least one heteroatom to said heteropoly compound. In essence insoluble homopolymolybdates are converted to soluble heteropolymolybdates to avoid the formation of a passivating layer.

U.S. Pat. No. 5,518,131 describes the use of ferric sulphate and ferric ammonium sulphate as the active ingredients in an etching bath for resist patterned molybdenum substrates.

U.S. Pat. No. 6,221,269 discloses a further improved method for etching and removing extraneous molybdenum or debris on ceramic substrates such as semiconductor devices and also for molybdenum etching in the fabrication of molybdenum photomasks. The method employs a multistep process using an acidic aqueous solution of a ferric salt to remove (etch) the molybdenum debris followed by contacting the treated substrate with an organic quaternary ammonium hydroxide to remove any molybdenum black oxides which may have formed on the exposed surface of treated molybdenum features in ceramic substrates.

Commonly used silver and molybdenum etching solutions are based on various combinations of acids from the group consisting of nitric acid, phosphoric acid, sulfuric acid, hydrochloric acid and acetic acid, usually in solutions containing various amounts of water.

In particular, nitric acid is one of the most frequently used oxidants in etching solutions. The problem with nitric acid based etching solutions, however, is that they are known for their non-uniform etch results which are difficult to reproduce. It has been suggested that the problems associated with nitric acid based etching solutions may be related to the dependence of their etching rate on the concentration of the undissociated acid present in the etchant solution (S. O. Izidinov, A. M. Suskin, and V. I. Gaponenko, Importance of kinetic and diffusion layer in the kinetics of coupled electrochemical reactions occurring in silicon etching in the HNO₃—HF system. Soviet Journal of Electrochemistry, 25, 418-25 (1989); M. Scholten and J. E. A. M. v. d. Meerakker, On the mechanism of ITO Etching: The Specificity of Halogen Acids. Journal of Eletrochemical Society, 140, 471-5 (1993)). Solvents with a low dielectric constant have been used to reduce the amount of undissociated acid in such etchants. The concentration of undissociated acid will also considerably increase in solutions with acid concentrations exceeding 5M (S. O. Izidinov, A. M. Suskin, and V. I. Gaponenko, Importance of kinetic and diffusion layer in the kinetics of coupled electrochemical reactions occurring in silicon etching in the HNO₃—HF system. Soviet Journal of Electrochemistry, 25, 418-25 (1989); M. Scholten and J. E. A. M. v. d. Meerakker, On the mechanism of ITO Etching: The Specificity of Halogen Acids. Journal of Eletrochemical Society, 140, 471-5 (1993); J. E. A. M. v. d. Meerakker, P. C. Baarslag and M. Scholten, On the mechanism of ITO Etching in Halogen Acids: The Influence of Oxidizing Agents. Journal of Electrochemical Society, 142, 2321-5 (1995)).

A general etching bath composition contains nitric acid, phosphoric acid, and acetic acid, often combined with further additives.

U.S. Pat. No. 4,629,539 and U.S. Pat. No. 4,642,168 describe mixtures of these acids as the electrolyte in an electrochemical etching method for the patterning of aluminum or aluminum-copper alloys.

U.S. Pat. No. 5,639,344 and U.S. Pat. No. 5,885,888 disclose a similar etching composition comprising at least phosphoric acid, nitric acid and acetic acid, with chromic acid added therein as an additional oxidant for the wet chemical etching of aluminum oxide layers.

Etching systems based on nitric acid are not entirely understood with respect to their etching mechanism, although it does seem that certain compounds are important as hereinafter discussed in greater detail.

A particular important compound is nitrogen dioxide (NO₂), which has been used as the sole source of the active etching agent as disclosed in U.S. Pat. No. 4,497,687 for a process of etching copper or other metals.

Another important component is nitrous acid (HNO₂), which according to U.S. Pat. No. 4,846,918 and U.S. Pat. No. 4,927,700 catalyses the dissolution of metallic copper in nitric acid based etchants. Addition of a scavenger for nitrous acid may accordingly even allow control of the etching process with such solutions.

U.S. Pat. No. 5,266,152 discloses a method of etching comprising preparing an etching solution containing hydrofluoric acid, nitric acid and optionally acetic acid and etching while adding a nitrite ion or a medium for producing nitrite acid ion to the etching solution. Preferably the concentration of nitrite ion in the etching solution is detected based on the concentration of NOₓ in the gas phase, which is in an equilibrium relation with the etching solution and necessary nitrite ions are added to the etching solution based on the concentration of NOₓ.

U.S. Pat. No. 5,376,214 further discloses that control of the NOₓ concentration may alternatively be achieved in such a process via electrodes immersed in the etching solution serving as a detector for uniformly controlling the nitrite ion concentration in the etching solution.

U.S. Pat. No. 5,324,496 proposes that maintaining a high concentration of highly oxidized nitrogen species, such as HNO₃ and NO₂, and thus a high etching rate may be achieved by maintaining a respective etching solution in an oxidizing atmosphere, which for instance, contains a high dioxygen concentration, to re-oxidize reduced nitrogen oxide species, such as HNO or NO, which are products of the etching process.

While acetic acid is often used in HNO₃ based etching solutions, trifluoroacetic acid is rarely proposed as an alternative.

U.S. Pat. No. 4,230,522 mentions trifluoroacetic acid as an alternative to acetic acid in an etching solution based on nitric acid and phosphoric acid for the etching of aluminum, silicon or alloys thereof as a diluting and leveling agent, but the specific use thereof is not specifically described.

Trifluoroacetic acid and derivatives thereof have furthermore been proposed as the active ingredient in plasma dry-etching systems as described in U.S. Pat. No. 5,626,775 and EP 0774778A.

Goetting et al (L. B. Goetting, T. Deng and G. M. Whitesides, Microcontact printing of Alkanephosphonic acids on Aluminium: Pattern Transfer by Wet Chemical Etching. Langmuir, 15, 1182-91 (1999)) reported patterning of aluminum layers by μCP using an alkanephosphonic acid as the ink. They found that the best resolution of the printed pattern could be obtained by etching the aluminum layer with a strongly acidic etching solution containing phosphoric, acetic and nitric acids and water in a ratio of 16:1:1:2.

Etching more than one layer at a time requires a very balanced etching system that provides comparable etching rates for the different materials in the various layers.

U.S. Pat. No. 4,345,969 discloses an etching method for the one-step etching of a three layer titanium-nickel-copper metallization. The etch solution comprises about 1.8 to 2.0 moles/liter hydrofluoric acid, about 2.5 to 4.0 moles/liter acetic acid, about 8.7 to 9.0 moles/liter nitric acid and balance water. Use of the solution permits the patterned etching of sequential layers of titanium, nickel and copper without excessive attack of underlying silicon dioxide layers.

U.S. Pat. No. 4,220,706 discloses an etching solution for multi-layered metal layers comprising an aqueous solution of from 0.5 to 50% by weight of nitric acid, from 0.03 to 1.0% by weight of hydrofluoric acid, from 0.05 to 0.5% by weight of hydrogen peroxide and from 0.1 to 1.0% by weight of sulfuric acid. The solution is compatible with photolithographic techniques and uniformly etches three or more metals.

There are a couple of etching baths known for silver that have proven useful on small laboratory scale samples in combination with microcontact printing but these do not allow homogenous etching of thin silver layers on larger substrates. They are either neutral or only moderately acidic or basic. Molybdenum etching on the other hand requires strongly basic or acidic etching conditions, but these have not been reported for use in combination with microcontact printing. A multi-layer etching method for silver (alloy) and molybdenum (alloy) layers is not known.

Etching baths composed of nitric acid and acetic acid are known and being used for etching a variety of metals. The addition to and control of low oxidation state nitrogen oxo compounds in such solutions has proven useful. None of the above have to date been used for microcontact printed substrates.

In general there are few examples of one-step multi-layer etching systems and none to date have been useful for silver or molybdenum etching. It is noted that in general the etching solution used in the second etching step must usually etch the metal of the second layer faster than the metal of the first layer, to obtain a useful result. Furthermore, an etch resist employed should be stable against both etching solution, if not the second etching solution should be 100% selective for the second metal, which hardly ever is the case.

A further problem that needs to be addressed in the development of microcontact printed samples is the formation of pinholes during the etching process. Pinholes are often observed in these samples as a result of the extremely small thickness of usually less than a few nanometers of the used SAM etch resist.

Geissler et al (M. Geissler et al. Strategies for Etching Microcontact-printed Metal Substrates, in the 200^{th} Meeting of the Electrochemical Society. 2001. San Francisco, Calif., USA; M. Geissler, H. Schmid, A. Bietsch, B. Michel and E. Delamarche, Defect Tolerant and Directional Wet Etch Systems for using Monolayers as Resists. Langmuir, 18, 2374-7 (2002)) have shown recently that the formation of defects during etching can be reduced by the addition of a SAM-stabilizing agent. Etching printed monolayers of eicosanethiol (ECT) on gold with an CN/O₂ etching bath containing 1-octanol at half saturation showed a significant reduction in the density of defects compared to an octanol-free etching bath, especially at the periphery of the printed structures. This “defect healing effect” was ascribed to the high affinity of molecules like 1-octanol for defects in the SAMs but not for the bare gold substrate, as hereinafter discussed in greater detail.

In line with the above Geissler publication, US 2004/0200575 describes a wet etching system for selectively patterning substrates having regions covered with SAMs, and controlling the etch profile thereof, the system comprising a) a liquid etching solution; and b) at least one additive to the liquid etching solution having a higher affinity to the regions of the substrate covered with SAMs than to the other regions of the substrate. The liquid etching solution comprises a CN/O₂ etching composition. For the additive, linear molecules with an alkyl chain and a polar head group are described as preferred, such as long chain alcohols, long chain acids, long chain amines, long chain sulfates, long chain sulfonates, long chain phosphates, long chain nitrites, long chain phosphonic acids and long chain alkanethiols. Specifically disclosed additives include hexadecanethiol and 1-octanol.

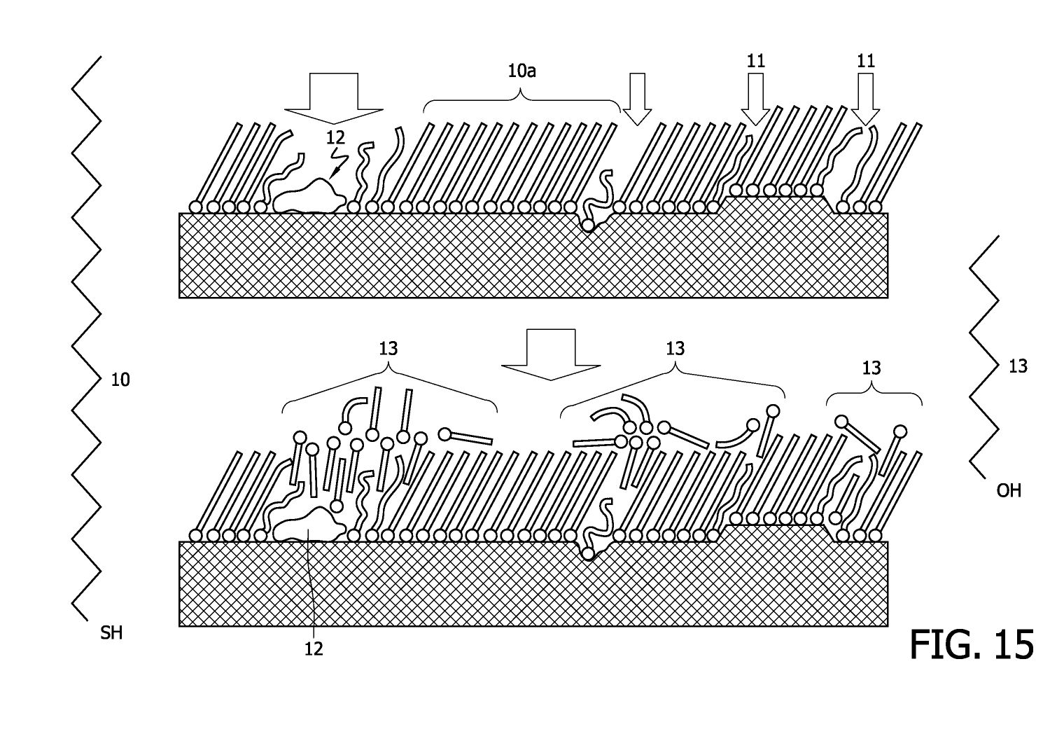

FIG. 15 illustrates this “defect-healing” or “defect-sealing” effect of the 1-octanol additive schematically. 1-octanol firstly is at its alkyl end lipophilic and therefore has an affinity for the defects in the monolayer into which it may insert or which it may cover. Secondly it is incapable of forming a stable SAM on metals like gold and thirdly it has a poor solubility in the etch bath to favor its healing state (M. Geissler, H. Schmid, A. Bietsch, B. Michel and E. Delamarche as above, Defect Tolerant and Directional Wet Etch Systems for using Monolayers as Resists. Langmuir, 18, 2374-7 (2002)). The hydroxyl end group does, however, still provide the 1-octanol molecule with a sufficient hydrophilicity to make it to some extent soluble in water. This is the only report of the utilization of such as effect for stabilizing SAM-resists against wet chemical etchants.

According to French et al (M. French and S. E. Creager, Enhanced Barrier Properties of Alkanethiol-Coated Gold Electrodes by 1-Octanol in Solution. Langmuir, 14, 2129-33 (1998)) 1-octanol does fill in defects in alkanethiol monolayers and even increases the overall thickness of the barrier layer. They further found that the properties of the combined alkanethiol/1-octanol barrier layers depend critically on the chain length of the alkanethiol. Creager et al (S. E. Creager and G. K. Rowe, Alcohol Aggregation at Hydrophobic Monolayer Surfaces and its Effect on Interfacial Redox Chemistry. Langmuir, 9, 2330-6 (1993)) also reported a dependence on the alkanethiol barrier properties on the chain length of the used alkyl alcohol additive.

Bain et al (C. D. Bain, P. B. Davies, and R. N. Ward, In-Situ Sum-Frequency Spectroscopy of Sodium Dodecyl Sulfate and Dodecanol Coadsorbed at a Hydrophobic Surface. Langmuir, 10, 2060-3(1994)) and Ward et al (R. N. Ward, P. B. Davies, and C. D. Bain, Coadsorption of Sodium Dodecyl Sulfate and Dodecanol at a Hydrophobic Surface. Journal of Physical Chemistry B, 101, 1594-601 (1997)) investigated the co-adsorption of sodium dodecyl sulphate (SDS, CH₃(CH₂)₁₁OSO₃Na) and 1-dodecanol (DD, CH₃(CH₂)₁₁OH) at octadecanethiol SAMs from aqueous solution. According to their results SDS and DD form a second monolayer, in which both the SDS and DD molecules contain few gauche defects, on top of the ODT SAM. Even at a very high SDS/DD concentration ratio of about 600/1 the mixed layer still contains about 63% DD and 37% SDS in neutral solution.

U.S. Pat. No. 4,632,727 discloses an etching bath composition for copper etching comprising nitric acid, water, a polymer, a surfactant and sulfuric acid or methane sulfonic acid as an alternative to sulfonic acid only. This bath is not intended for microcontact printed substrates.

U.S. Pat. No. 3,935,118 and U.S. Pat. No. 4,032,379 disclose an etching bath composition for etching of magnesium and alloys thereof comprising an aqueous solution of a strong inorganic acid, preferably nitric acid, and adjuvant. Those adjuvant comprise organic phosphonic acids and organic sulfonic acids. Again this bath is not suggested for use with microcontact printed substrates and the disclosure is limited to magnesium etching only.

US 2003/0010241 discloses a strategy for sealing defects in SAMs and reinforcing the SAM stability against solutions with a certain polarity. More specifically, US 2003/0010241 claims a patterning method for the formation of a surface pattern consisting of contrasting hydrophobic and hydrophilic areas, in that a first hydrophilic (or hydrophobic) monolayer consisting of a first type of hydrophilic (or hydrophobic) molecules is formed on the surface of a substrate by microcontact printing and in that a second now hydrophobic (or hydrophilic) monolayer is formed in the remaining uncovered areas of the surface of the substrate by adsorption of a second type of now hydrophobic (or hydrophilic) molecules from solution, wherein the second type of molecules has a shorter chain length than the first type of molecules, or wherein the second type of molecules is adsorbed from a solution in an organic solvent (or in water). This second type of molecules may reside in defects in the monolayer of the first type of molecules as well.

There is a need, therefore, for an improved etchant solution, and etching method using the same, which alleviates the problems of the prior art.

According to the present invention, there is now provided an etchant solution for patterned etching of at least one surface or surface coating of a substrate, which solution comprises nitric acid, a nitrite salt, a halogenated organic acid represented by the formula C(H)ₙ(Hal)ₘ[C(H)ₒ(Hal)ₚ]_{q}CO₂H, where Hal represents bromo, chloro, fluoro or iodo, where:

n is 0, 1, 2 or 3, and m is 0, 1, 2 or 3, with the proviso that m+n=3;

o is 0 or 1, p is 1 or 2, with the proviso that o+p=2;

q is 0 or 1, with the proviso that q+m =1, 2, 3 or 4;

and balance water.

The function of the different components is hereinafter discussed in greater detail.

Preferably, the halogenated organic acid comprises a mono-, di- or tri-haloacetic acid, even more preferably a mono-, di- or tri-fluoroacetic acid, especially trifluoroacetic acid. A halogenated organic acid for use in an etchant solution according to the present invention may alternatively comprise a halogenated propionic acid and suitable propionic acid derivatives can be represented by the following generic formulae CH₂HalCHHalCO₂H and CH₃CHHalCO₂H. Each Hal as present in a halogenated organic acid for use in accordance with the present invention, can be the same or different, thus allowing for substitution by one, or more than one, type of halogen atom in the organic acid.

Preferably, the nitrite salt is an alkali metal nitrite salt, and it is particularly preferred that the nitrite salt is sodium nitrite.

It is important that the concentration of nitric acid is maintained within a relatively small range, such as a concentration range of about 5-20 vol % (preferably about 12 vol %). On the other hand, the observed pinhole density is rather insensitive to the halogenated organic acid concentration, and as such a concentration range of about 10-95 vol % (preferably about 36 vol %) may be used. The nitrite concentration allows for control of the etching rate and may thus also be varied in a wide range of concentrations, and typically a concentration range of about 10⁻⁵ to 5 molar (preferably about 0.1 molar) is employed. The remaining part of the etchant solution is water, the concentration of which depends on the concentration of the other components. Generally an amount of 10% of water is considered a minimum for use in an etchant solution according to the present invention.

In certain applications an etchant solution according to the present invention can further comprise additional components, such as phosphoric or sulfuric acid, or derivatives thereof, although this is not a requirement for an etchant solution of the invention and in certain embodiments it may be preferred that these additional components are not present. For example, phosphoric acid may be present in a small amount, such as less than about 10%. Even very small amounts of sulfuric acid (1-2% or even less) can cause a dramatic increase in the achievable etching rate and as such may be beneficial for some applications. Generally, however, the inclusion of sulfuric acid is not required for etching of microcontact printed samples, with the presence of sulfuric acid typically reducing the selectivity of the etching solution against alkanethiol SAMs, resulting in a much increased pinhole density. The presence of certain sulfonic and/or phosphonic acid derivatives may, however, be beneficial as hereinafter described in greater detail.

Etching solutions based on HNO₃, such as provided by the present invention, are one of the most complicated etchants. No general mechanism can describe the actual metal dissolution process in all known applications. The main reason is the fact that there are many species, which are in equilibrium relation with dissociated and undissociated HNO₃, participating in the etching reaction. Some of these equilibria are as shown below.

Nitric acid is a strong acid that dissociates in polar solvents:

HNO₃ [symbol] H⁺+NO₃⁻ (1)

It is formed by dissolution of nitrogen dioxide in water:

3NO₂+H₂O [symbol] 2HNO₃+NO (2)

This reaction is the sum of at least four independent equilibrium reactions:

2NO₂ [symbol] N₂O₄ (3)

N₂O₄ [symbol] NO⁺+NO₃⁻ (4)

NO⁺+H₂O [symbol] H⁺+HNO₂ (5)

HNO₂+NO₂ [symbol] HNO₃+NO (6)

It is important to note that all the above reactions are readily reversible and the different components of these equilibria will always be present in “nitric acid” solutions in varying concentrations. The individual concentration of each component is determined by the presence and concentration of other components of the etching solution.

The question by which component or components the actual metal oxidation and dissolution reaction is mainly determined remains an open question for many applications. It has been proposed that in some cases the concentration of undissociated acid is the most important factor, indicating that this might be the actual oxidizing species (S. O. Izidinov, A. M. Suskin, and V. I. Gaponenko, Importance of kinetic and diffusion layer in the kinetics of coupled electrochemical reactions occurring in silicon etching in the HNO₃—HF system. Soviet Journal of Electrochemistry, 25, 418-25 (1989); M. Scholten and J. E. A. M. v. d. Meerakker, On the mechanism of ITO Etching: The Specificity of Halogen Acids. Journal of Eletrochemical Society, 140, 471-5 (1993)). Nevertheless an inspection of FIG. 6 (data from A. F. Holleman and E. Wieberg, Lehrbuch der Anorganischen Chemie. 91-100. Aufl. Ed. 1985, Berlin: Walter de Gruyter) clearly demonstrates that many of the species present in nitric acid solutions have an equally high or even higher oxidizing power when compared to nitric acid. A discussion of the individual reactions of these species with different metals is given by Addison (C. C. Addison, Dinitrogen Tetroxide, Nitric Acid, and Their Mixtures as Media for Inorganic Reactions. Chemical Reviews, 80, 21-39 (1980)). That there are more than one species involved in the metal oxidation reaction is clearly indicated by the observation that the etching reaction with nitric acid based solutions is autocatalytic and the control of the same is important for the selectivity of the etchant against the used resist.

Following equation (7) describes the principal oxidation of a metal by nitric acid, as it may occur in water free etching solutions.

M+n/2HNO₃+nH⁺→Mⁿ⁺+n/2HNO₂+n/2H₂O (7)

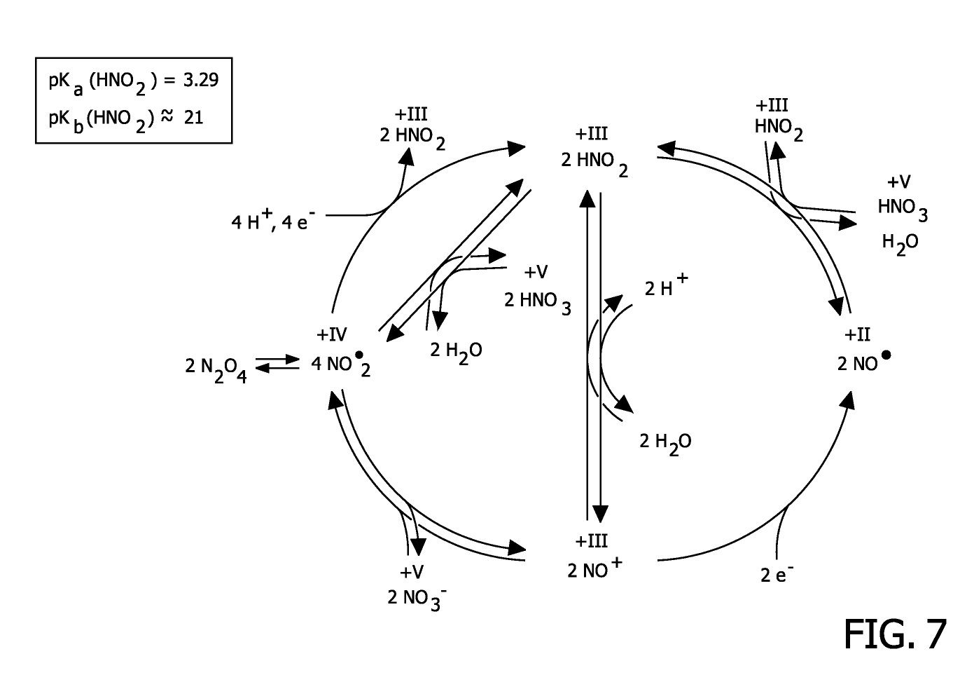

Although this often used description is oversimplified, it indicates that nitrous acid (HNO₂) is a principal oxidation product of the dissolution reaction. As was shown above, nitrous acid does further participate in other equilibrium reactions. Some important equilibria, which are especially important in water based etching solutions are summarized in FIG. 7. HNO₂ is a moderate acid (pKₐ=3.29) and a weak base (pK_{b}=21). It can thus be protonated in strongly acidic media to form NO⁺ after dissociation of the protonated species:

HNO₂+H⁺ [symbol] H₂NO₂⁺ (8)

H₂NO₂⁺ [symbol] NO⁺+H₂O (9)

NO⁺ is a strong oxidizing agent and may oxidize a metal M forming NO as follows

M+nNO⁺ [symbol] Mⁿ⁺+nNO (10)

which in turn reacts with nitric acid to form back nitrous acid

2NO+HNO₃+H₂O [symbol] 3HNO₂ (11)

The important fact is that in each reaction cycle more HNO₂ is formed than it was present before, which causes the autocatalytic effect. The more metal is etched the more oxidizing species are produced and thus the faster becomes the etching reaction.

An alternative autocatalytic cycle is shown in the left half of FIG. 7. In an equilibrium reaction NO⁺ comproportionates with NO₃⁻ to form NO₂, which in turn exists in equilibrium with N₂O₄ as already described in equations 4 and 3:

NO⁺+NO₃⁻ [symbol] 2NO₂ [symbol] N₂O₄ (12)

As will be explained further below, this comproportionation reaction is of particular importance for the selectivity of the etching solution. In reaction (12) two charged particles react with each other to form two neutral NO₂ molecules. To which extent the comproportionation reaction occurs, depends on the reaction medium and the other components present. In a very polar solution, thus a medium with a high dielectric constant and many ionic species, the ionic couple on the left hand side of the equation will be stabilized while in a less polar medium, thus a medium with a lower dielectric constant and fewer ionic species, the equilibrium will be shifted to the right. Thus the overall composition of the solution determines the relative concentration of the species in reaction (12).

According to FIG. 6 the NO₂/N₂O₄ couple is an even stronger oxidant than HNO₃ and can oxidize a metal M as described in equation (13).

M+nNO₂+nH⁺ [symbol] Mⁿ⁺+nHNO₂ (13)

The product of this reaction is again nitrous acid. Another inspection of the overall reaction cycle in the left of FIG. 7 reveals that again the amount of HNO₂ molecules is doubled in each reaction cycle, thus it represents an alternative autocatalytic cycle.

An uncontrolled autocatalytic reaction as described above results in inhomogeneous and poorly reproducible etching reactions because it strongly changes only the local concentration of reactive species resulting in locally different etching rates. Controlling this reaction becomes, therefore, dramatically more important when the size of the substrate to be etched increases.

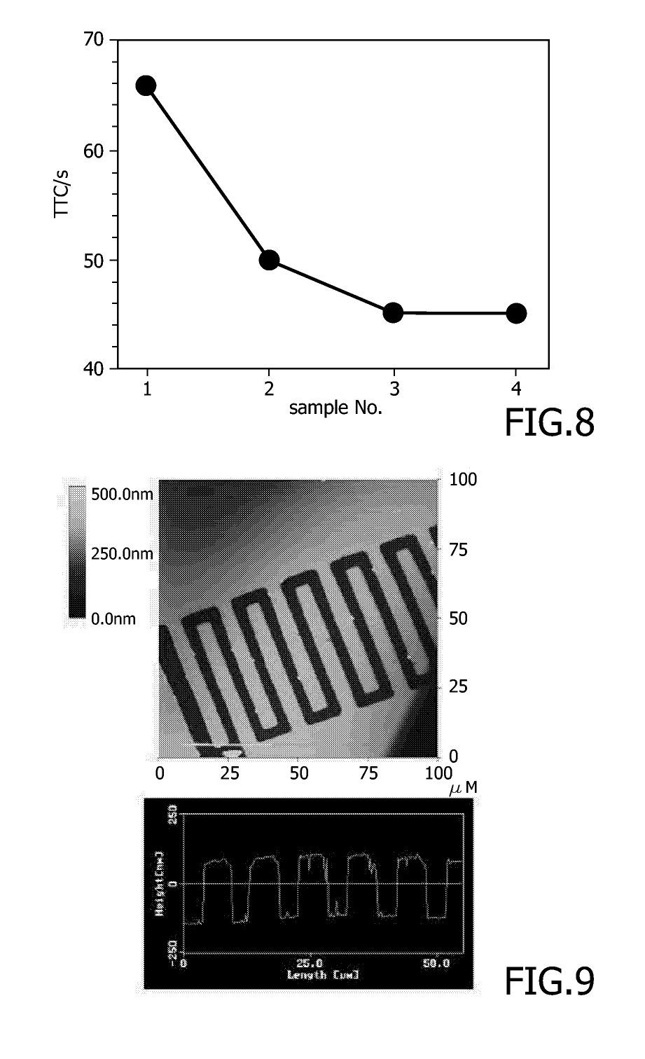

It has become clear from the above that although nitric acid or nitrate ions are the ultimate source of the oxidizing power, species in a lower oxidation state (FIGS. 6 and 7) can play a dominant role in the actual etching reaction. The lower the initial concentration of these species, the stronger is the effect of the concentration increase of these species resulting from their generation in the autocatalytic reaction. FIG. 8 shows the decrease of the time to clear (TTC, the time necessary to completely remove all metal layers from the above described APC/Mo(Cr) substrates) as a function of the number of substrates etched in an etching bath composed of nitric acid, phosphoric acid and water. As a result of the build up of a higher concentration of reduced nitrogen oxo species, the TTC decreases rapidly in the beginning and the effect becomes smaller with an overall increasing concentration of these species later in the series.

This effect can be reduced by the addition of low oxidation state nitrogen oxo compounds, such as nitrogen oxide (NO) or nitrite (NO₂⁻) salts, to the etching solution in a sufficiently high concentration in the first place. This results in higher overall etching rates and a more homogeneous etching reaction for large substrates.

In particular, in accordance with the present invention, we employ a nitrite salt, such as an alkali metal nitrite salt, more specifically sodium nitrite (NaNO₂) or potassium nitrite (KNO₂), most preferably in an amount equivalent to a concentration of about 0.1M, which yields the best results in the herein disclosed etchant solution of the invention further comprising nitric acid, a halogenated organic acid and water. In general, the addition of an amount of nitrite equivalent to a concentration of 10⁻⁵ and 5 molar, preferably 0.01-1 molar, is beneficial.

Many commercial etching solutions are composed of various mixtures of nitric acid, phosphorous acid and often also acetic acid. The role of nitric acid as an oxidant has been discussed above. It also provides nitrate ions as possible counter ions or ligands for the dissolved metal ions.

The role of phosphoric acid in such etching solutions is somewhat less clear. First of all, it is a solvent. In some cases it is added as a corrosion inhibitor (C. C. Addison, Dinitrogen Tetroxide, Nitric Acid, and Their Mixtures as Media for Inorganic Reactions. Chemical Reviews, 80, 21-39 (1980)). The main aspect of this function is the formation of various metal phosphate species that have a low solubility and may thus cause passivative layers on the substrate surface. Due to its high acidity it will also have an impact on the equilibria described above and will thus influence the chemistry of the various nitrogen oxo species. Furthermore, phosphoric acid has a high viscosity, which is an important aspect with respect to etching reactions that are diffusion controlled. In those cases controlling the viscosity of the medium to some extent allows control of the rate and homogeneity of the etching reaction.

Acetic acid to some extent fulfils functions similar to those of phosphoric acid. It is a solvent, it forms metal complexes of low solubility in water and it is an acid. Additionally, it is, other than nitric acid and phosphoric acid, an organic acid. Being an only moderately strong acid, it gives the solution a somewhat organic and less polar character. As a result it has a strong impact on the above described equilibria and will thus influence the chemistry of the various nitrogen oxo species significantly.

In accordance with an etchant solution as provided by the present invention we employ a halogenated organic acid, preferably trifluoroacetic acid (TFA), which provides significant advantage over the use of phosphoric acid or acetic acid, and in particular the use of a halogenated organic acid, preferably TFA, provides advantages for patterned etching of microcontact printed substrates.

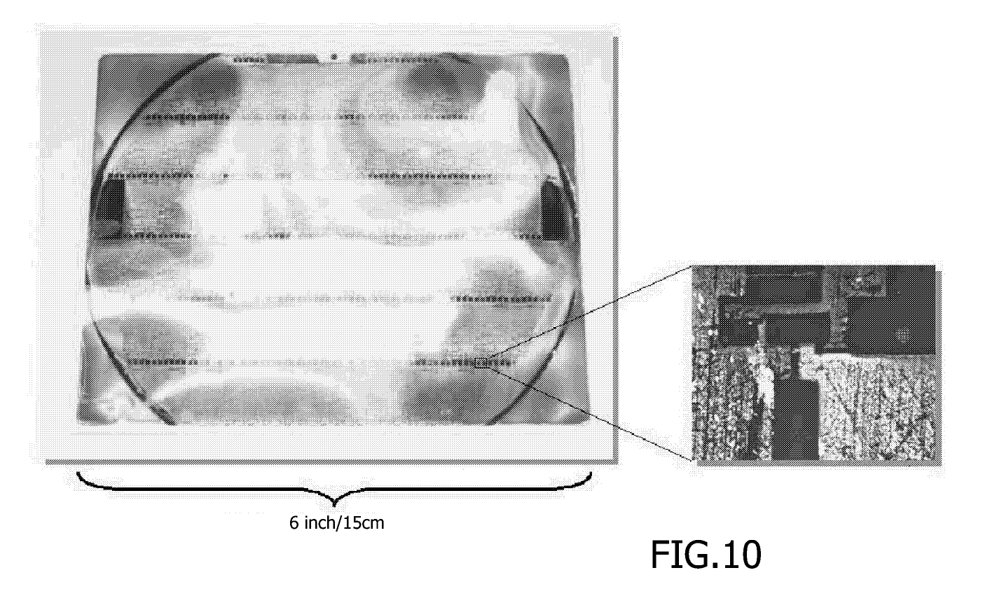

In a preferred embodiment of the present invention, where the etchant solution is employed for a microcontact-printed APC/Mo(Cr) sample, during early optimization steps of the etching solution we found that a bath composed of nitric acid, phosphoric acid and water (volume ratio: 3/9/13) etched the described microcontact-printed APC/Mo(Cr) samples with an acceptable resolution and selectivity as long as the size of the samples did not exceed about 1-2 cm². FIG. 9 shows an atomic force microscopic picture of such a small APC/Mo(Cr) sample (size 1×2 cm²) printed with octadecanethiol and subsequently etched in a solution containing nitric acid, phosphoric acid and water (volume ratio: 3/9/13). FIG. 10 shows a sample of the same composition and treated the same way with the only difference that the sample size in this case was 10×15 cm². From this it becomes clear that although the described etching solution yields reasonable results for small substrates, it is not useful for etching larger substrates of the described composition due to its very inhomogeneous etching behavior and the poor reproducibility of the etching results.

From the experiments with the various phosphoric acid concentrations and a constant nitric acid concentration we also found that by reducing the phosphoric acid concentration, etching becomes more homogeneous on the larger substrates, probably due to a decrease in the viscosity of the etching solution as a result of the lower content of this high viscosity component. This was accompanied by an unchanged poor pattern quality of the etched substrates and a lower etching rate. We could compensate for reduced etching rate by the addition of sodium or potassium nitrite for the reasons explained above. The quality of the patterns did not, however, improve significantly as a result of this modification.

Therefore we replaced the phosphoric acid stepwise and eventually completely with acetic acid thereby gradually improving the etch quality. The further reduced etch rate was again compensated for by the addition of even higher concentrations of sodium or potassium nitrite.

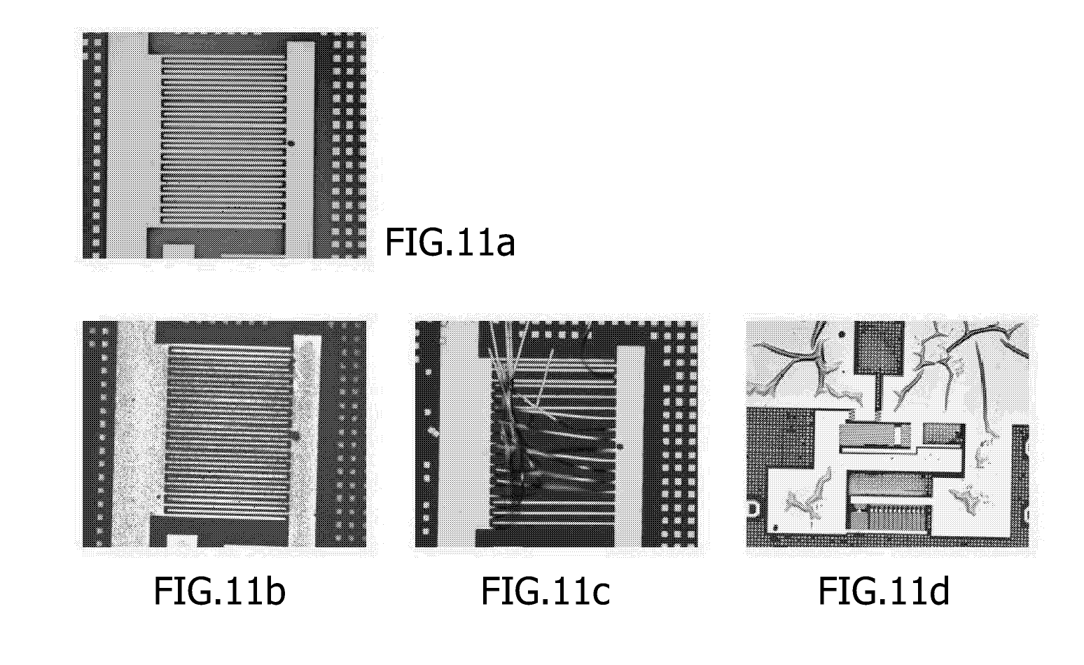

We found that a rather homogeneous etching behavior could be obtained with a solution composed of nitric acid, acetic acid and water (vol %: 12/36/52). The problem with this solution, however, was that the resulting pattern still suffered from a relatively large density of pinholes. FIG. 11 gives an overview of microscopy photographs of the most often encountered shortcomings in the developed pattern of the microcontact-printed APC/Mo(Cr) substrates.

We succeeded in reducing the number of pinholes significantly and also obtaining a generally much more homogeneous and better quality of the developed pattern by replacing the acetic acid content completely by trifluoroacetic acid (TFA). The best results were obtained with an etching bath of the following composition: about 60 mL of nitric acid (65%), about 180 mL of trifluoroacetic acid (100%), about 260 mL of water and about 3.45 g of sodium nitrite.

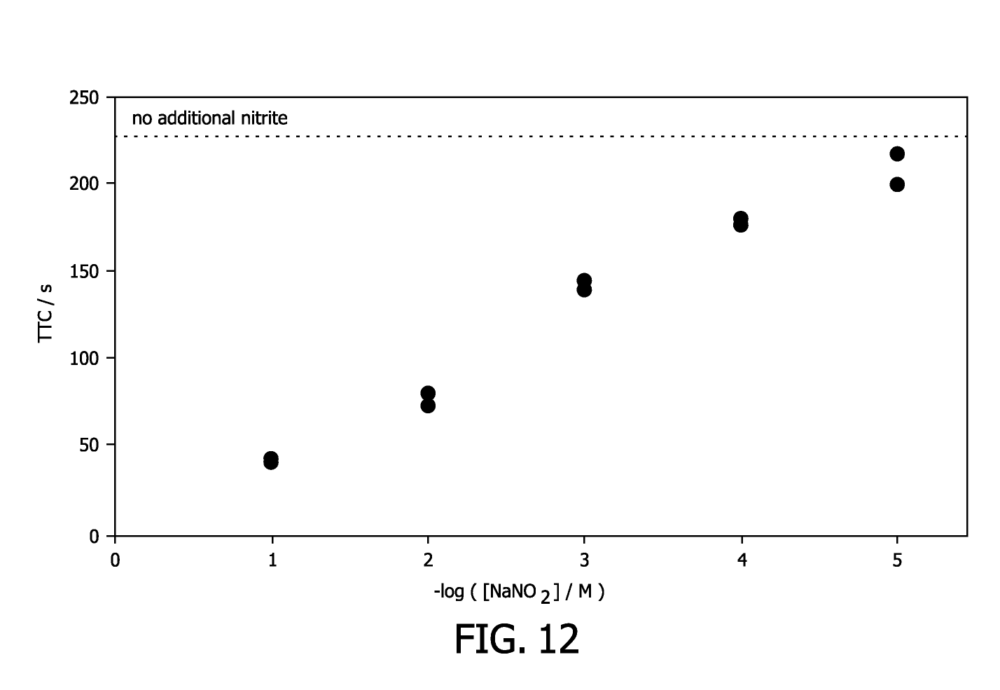

FIG. 12 shows the effect of a variation of the nitrite concentration on the time to clear (TTC, the time necessary to completely etch away the APC and the Mo(Cr) layers of the above substrates) in an etching bath of the composition given above. Without the addition of a nitrite salt, a TTC of about 230 seconds was observed (dotted line in FIG. 12). The concentration of added sodium nitrite was varied between 10⁻⁵M and 1M (−log([NO₂⁻]/M)=5−0). A strong almost linear dependence of the TTC on the negative logarithm of the nitrite concentration (−log([NO₂⁻]/M)) was observed in this range. The strong decrease of the TTC, thus the strong increase of the etching rate with an increasing nitrite concentration can be used to fine tune the etching properties of the bath, however, considering that the etch quality does also depend on the nitrite concentration, in particular with respect to the homogeneity of the etching rate and the density of pinholes. At the preferred nitrite concentration of 0.1M a TTC of about 60 seconds was obtained.

TFA is a very strong acid as illustrated in Table 2 below, and without wishing to be bound by theory, there are at least two possible explanations for the superior performance of TFA containing etching baths as now provided by the present invention.

TABLE 2
Acidity constants of relevant acids

| Formula | Name | T/° C. | Step | pKₐ | Reference |
|---|---|---|---|---|---|
| HNO₃ | Nitric acid | 20 | 1 | −1.3 | a |
| HNO₂ | Nitrous | 25 | 1 | 3.25 | b |
| | acid | | | | |
| H₃PO₄ | Phosphoric | 25 | 1 | 2.16 | b |
| | acid | | 2 | 7.21 | b |
| | | | 3 | 12.32 | b |
| HO₂CCH₃ | Acetic | 25 | 1 | 4.756 | b |
| | acid | | | | |
| HO₂CCH₂OH | Glycolic | 25 | 1 | 3.83 | b |
| | acid | | | | |
| HO₂CCF₃ | Trifluoro- | 25 | 1 | 0.52 | b |
| | acetic acid | | | | |

a = F. W. Kuster and A Thiel, Rechentafeln fur die Chemische Analyse. 103. Aufl. ed. 1985, Berlin: Walter de Gruyter.
b = D. R. Lide, ed. CRC Handbook of Chemistry and Physics. 84^{th} Edition ed. 2003, CRC Press: Boca Raton.

One consideration is that TFA is a stronger acid than phosphoric acid and acetic acid due to its three electron withdrawing fluoro substituents. Thus it will in aqueous solutions be dissociated to a greater extent than phosphoric or acetic acid. Consequently TFA-containing solutions will be more ionic or polar. FIG. 7 gives an overview of some of the more relevant oxidizing species in nitric acid solutions. Of particular interest is the equilibrium reaction between the two very strong oxidants NO⁺ and NO₂/N₂O₄.

NO⁺+NO₃⁻ [symbol] 2NO₂ [symbol] N₂O₄ (12)

Since the species on the left side of equilibrium reaction (12) (NO⁺ and NO₃⁻) are charged species and the species on the right hand side (NO₂ and N₂O₄) are neutral species, the relative concentrations of these species will be strongly influenced by the polarity of the medium. The ionic species on the left hand side will be stabilized in a more polar environment, whereas the neutral species on the right hand side will be stabilized in a less polar environment. Consequently a solution containing TFA instead of acetic or phosphoric acid at the same concentration will have a relatively higher concentration of NO⁺ than a solution containing any of the other two acids.

The etch resist used in microcontact printing in a preferred embodiment of the present invention is a hydrophobic self assembled monolayer (SAM). The penetration of the

SAM by active molecular species from the etching solution results in the formation of pinholes. Not all species have the same chance to penetrate this SAM. Hydrophobic and in particular uncharged species can penetrate the hydrophobic SAM more easily than hydrophilic or charged species.

Thus a SAM resist should be more stable against etching solutions in which the active species are hydrophilic and charged, such as NO⁺, than against those in which the active species are hydrophobic and uncharged, such as NO₂ and N₂O₄. Therefore, the more polar TFA etchants should be less aggressive against the SAM and generate less pinholes in the final pattern than the phosphoric or acetic acid containing etchant and this is what has been found by the present inventors.

A second consideration is the stability of the SAM against the etchant due to its solvent properties rather than its oxidizing properties. As stated above, acetic acid containing etchants have a less polar character than a respective TFA-containing etchant. The molecules forming the SAM should consequently dissolve more easily in an etchant containing acetic acid and thus the stability of the SAM in such an etching solution should be reduced. However, we have also investigated the use of hydroxyacetic acid (glycolic acid, HOCH₂COOH, HA) instead of acetic acid and TFA. HA is also a stronger acid than acetic acid but due to its additional hydroxy group these molecules are much less hydrophobic than TFA. Nevertheless we found comparable pinhole densities in substrates etched with such an etching solution as in those etched with an acetic acid containing etchant, indicating that the hydrophobicity of the acetic acid derivative is no major argument for the observed effect. In fact even larger pinhole densities are observed for the very hydrophilic phosphoric acid.

Another inspection of FIG. 6 reveals that the reduction potentials of silver and molybdenum differ by as much as about 1 Volt.

Ag++e⁻ [symbol] Ag E₀=+0.80V(vs NHE) (14)

Mo³⁺+3e⁻ [symbol] Mo E₀=−0.20V(vs NHE) (15)

Therefore rather different etching rates would be expected for these two metals. The etching of molybdenum should proceed at a much higher rate than the etching of silver.

As discussed before, some metals form passivating layers during etching. In particular, molybdenum forms a passivating layer composed of molybdenum oxides. The formation of molybdenum acetates with a low solubility is also possible. To dissolve this passivating layer at a reasonable rate almost all known molybdenum etching solutions are either strongly basic or strongly acidic. Nevertheless, the formation of a passivating layer is the main reason for a practical etching rate that is lower than theoretically expected. Since the composition of this layer, and the kinetics of its dissolution, are dependent on the composition of the etching solution, the overall etching rate of molybdenum strongly depends on the composition of the etchant. For the herein disclosed etching composition, the etching rate for the 20 nm thick molybdenum or molybdenum chromium layer is comparable to that of the 200 nm thick silver or APC layer. In fact, in independent etching experiments with glass substrates bearing only a 20 nm molybdenum, a TTC of about 5-7 seconds was found, which compares well with a total etching time of about 60 seconds for a full 220 nm thick APC/Mo(Cr) stack. In general the etching rate for the molybdenum-chromium alloy (Mo(Cr)) is somewhat lower than for pure Mo.

We have further found that in addition to the actual individual components of the etchant solution, and the amounts thereof, the preparation procedure for the etchant solution itself is also important for the final etching performance. There is further provided by the present invention, therefore, a process of preparing an etchant solution substantially as hereinbefore described, which process comprises:
(a) mixing, under cooling, a halogenated organic acid represented by the formula C(H)ₙ(Hal)ₘ[C(H)ₒ(Hal)ₚ]_{q}CO₂H, where Hal represents bromo, chloro, fluoro or iodo, where:

n is 0, 1, 2 or 3, and m is 0, 1, 2 or 3, with the proviso that m+n=3;

o is 0 or 1, p is 1 or 2, with the proviso that o+p=2;

q is 0 or 1, with the proviso that q+m=1, 2, 3 or 4;

and a selected amount of water (typically at least about half of the water to be employed, and more preferably about two thirds of the water to be employed);
(b) adding nitric acid to a mixture obtained further to step (a) to obtain an acid-water mixture;
(c) mixing a nitrite salt and the remaining amount of water; and
(d) adding, under cooling, a solution obtained further to step (c), to the acid-water mixture obtained further to step (b), so as to thus provide an etchant solution in accordance with the present invention.

Step (a) is very exothermic and it is important that sufficient cooling is provided. Furthermore, addition of the nitrite salt is also a key step. Large amounts of nitrogen oxides will be released to the gas phase above the solution if the mixture has not been cooled down to room temperature, or more preferably below room temperature, before the addition of the nitrite solution obtained further to step (c). Prior to the addition of nitrite, it is important that sufficient water has been added to the acid mixture to release most of the hydrolysis energy. The nitrite should also not be added as a solid to the acid-water mixture to avoid local high concentrations of nitrite. Following these guidelines for the preparation of the etchant solution, good reproducible results are obtained in accordance with the present invention.

There is further provided by the present invention an etching bath containing an etchant solution substantially as hereinbefore described, suitable for use in a process of patterned etching of at least one surface or surface coating of a substrate as hereinafter described in greater detail. In such an etching bath as provided by the present invention, it is preferred that there is contained therein about 60 mL of nitric acid (65%), about 180 mL of trifluoroacetic acid (100%), about 260 mL of water and about 3.45 g of sodium nitrite.

A preferred aspect of the invention is the thus described novel etching bath, which in particular enables a new microcontact printing method for the patterning of metal substrate coatings to be provided in accordance with the present invention. With this invention, substrate coatings of the described composition can for the first time be microcontact printed and the printed pattern can be developed. The present invention is not, however, limited to microcontact printed substrates and an etchant solution as provided by the present invention may have utility in other patterning methods or any other method that requires etching of substrates bearing any of the indicated metals or other suitable materials.

According to the present invention, therefore, there is provided a process of providing a patterned substrate, which process comprises:
(a) providing a substrate including at least one surface or surface coating to be patterned;
(b) providing an etch resist on said surface or surface coating; and
(c) treating at least said surface or surface coating with an etchant solution substantially as hereinbefore described so as to selectively remove surface or surface coating material substantially not underlying said etch resist.

Preferably an etch resist for use in a method according to the present invention comprises at least one SAM, typically applied to the substrate surface or surface coating by microcontact printing. It is preferred that the substrate surface or surface coating to which a SAM as described above is to be applied, and the SAM-forming species, should be selected together such that the SAM-forming species terminates at one end in a functional group that binds to the substrate surface or surface coating.

A substrate surface or surface coating and SAM-forming molecular species are thus selected such that the molecular species terminates at a first end in a functional group that binds to the desired surface (the substrate or a surface film or coating applied thereto). As used herein, the terminology “end” of a molecular species, and “terminates” is meant to include both the physical terminus of a molecule as well as any portion of a molecule available for forming a bond with a surface in a way that the molecular species can form a SAM, or any portion of a molecule that remains exposed when the molecule is involved in SAM formation. A SAM-forming molecular species typically comprises a molecule having first and second terminal ends, separated by a spacer portion, the first terminal end comprising a functional group selected to bond to a surface (the substrate or a surface film or coating applied thereto), and the second terminal group optionally including a functional group selected to provide a SAM on the surface having a desirable exposed functionality. The spacer portion of the molecule may be selected to provide a particular thickness of the resultant SAM, as well as to facilitate SAM formation. Although SAMs of the present invention may vary in thickness, as described below, SAMs having a thickness of less than about 100 Angstroms are generally preferred, more preferably those having a thickness of less than about 50 Angstroms and more preferably those having a thickness of less than about 30 Angstroms. These dimensions are generally dictated by the selection of the SAM-forming molecular species and in particular the spacer portion thereof.

A wide variety of surfaces (exposing substrate surfaces on which a SAM will form) and SAM-forming molecular species are suitable for use in the present invention. A non-limiting exemplary list of combinations of substrate surface material (which can be the substrate itself or a film or coating applied thereto) and functional groups included in the SAM-forming molecular species is given below. Preferred substrate surface materials can include metals such as gold, silver, titanium, molybdenum, copper, cadmium, zinc, nickel, cobalt, palladium, platinum, mercury, lead, iron, chromium, manganese, tungsten and any alloys of the above typically for use with sulfur-containing functional groups such as thiols, sulfides, disulfides, and the like, in the SAM-forming molecular species; doped or undoped silicon with silanes and chlorosilanes; surface oxide forming metals or metal oxides such as silica, indium tin oxide (ITO), indium zinc oxide (IZO) magnesium oxide, alumina, quartz, glass, and the like, typically for use with carboxylic acids or heteroorganic acids including phosphonic, sulfonic or hydroxamic acids, in the SAM-forming molecular species; platinum and palladium typically for use with nitriles and isonitriles, in the SAM-forming molecular species. Additional suitable functional groups in the SAM-forming molecular species can include acid chlorides, anhydrides, hydroxyl groups and amino acid groups. Additional substrate surface materials can include germanium, gallium, arsenic, and gallium arsenide.

Preferably, however, a substrate for use in a method according to the present invention typically comprises a metal substrate, or at least a surface of the substrate, or a thin film or coating deposited on the substrate, on which the pattern is printed, comprises a metal, which can suitably be selected from the group consisting of gold, silver, titanium, molybdenum, copper, cadmium, zinc, nickel, cobalt, palladium, platinum, mercury, lead, iron, chromium, manganese, tungsten and any alloys of the above. Preferably the substrate surface to be patterned comprises at least one metal coating applied to an underlying substrate surface and as such it is preferred that a process substantially as hereinbefore described further comprises providing at least one surface metal coating to an underlying substrate surface and subsequently providing the etch resist on said surface metal coating. Preferably the at least one metal coating comprises a metal selected from the group consisting of gold, silver, titanium, molybdenum, copper, cadmium, zinc, nickel, cobalt, palladium, platinum, mercury, lead, iron, chromium, manganese, tungsten and any alloys of the above.

The exposed substrate surfaces to be coated with a SAM may thus comprise a substrate itself, or may be a thin film or coating deposited upon a substrate. Where a separate substrate is employed, it may be formed of a conductive, nonconductive, semiconducting material, or the like, such as silicon or glass, and suitably as hereinafter described in greater detail in the Examples a glass substrate is particularly suitable for use in a patterning method according to the present invention.

In a preferred embodiment of the present invention, at least one exposed metal coating to be patterned in accordance with the present invention is a silver coating, and even more preferably a silver alloy coating, such as an APC silver alloy (APC=98.1% Ag, 0.9% Pd, 1.0% Cu). It is further preferred in accordance with the present invention that a process substantially as hereinbefore described comprises applying to the substrate surface at least one adhesion coating prior to application of the exposed metal coating, so as to achieve a required high adhesion of the subsequently applied metal coating to the substrate. Suitable adhesion coatings can comprise molybdenum, titanium, or chromium, or alloys thereof, and a particularly preferred adhesion coating for use in accordance with the present invention can comprise molybdenum, and even more preferably a molybdenum alloy, such as a molybdenum-chromium alloy (97% Mo, 3% Cr). In an even more preferred embodiment of the present invention a combination of a silver alloy exposed surface coating and a molybdenum-chromium alloy adhesion coating is employed with a SAM-forming molecular species as the etch resist having at least one sulfur-containing functional group, such as a thiol, sulfide, or disulfide.

A SAM-forming molecular species may terminate in a second end opposite the end bearing the functional group selected to bind to particular substrate material in any of a variety of functionalities. The central portion of molecules comprising SAM-forming molecular species generally includes a spacer functionality connecting the functional group selected to bind to a surface and the exposed functionality. Alternatively, the spacer may essentially comprise the exposed functionality, if no particular functional group is selected other than the spacer. Any spacer that does not disrupt SAM packing is suitable. The spacer may be polar, nonpolar, positively charged, negatively charged, or uncharged. For example, a saturated or unsaturated, linear or branched hydrocarbon or halogenated hydrocarbon containing group may be employed. The term hydrocarbon as used herein can denote straight-chained, branched and cyclic aliphatic and aromatic groups, and can typically include alkyl, alkenyl, alkynyl, cycloalkyl, cycloalkylalkyl, aryl, arylalkyl, arylalkenyl and arylalkynyl. The term “hydrocarbon containing group” also allows for the presence of atoms other than carbon and hydrogen, typically for example, oxygen and/or nitrogen. For example, one or more methylene oxide, or ethylene oxide, moieties may be present in the hydrocarbon containing group; alkylated amino groups may also be useful. Suitably, the hydrocarbon groups can contain up to 35 carbon atoms, typically up to 30 carbon atoms, and more typically up to 20 carbon atoms. Corresponding halogenated hydrocarbons can also be employed, especially fluorinated hydrocarbons. In a preferred case the fluorinated hydrocarbon can be represented by the general formula F(CF₂)ₖ(CH₂)₁, where k is typically an integer having a value between 1 and 30 and 1 is an integer having a value of between 0 and 6. More preferably, k is an integer of between 5 and 20, and particularly between 8 and 18. It is of course recognized that although the above are given as preferred ranges for the values of k and l, the particular choice of k and l can be varied in accordance with the principles of the present invention. It will also be appreciated that the term “hydrocarbon containing group” also allows for the presence of atoms other than carbon and hydrogen, typically O or N, as explained above.

The above hydrocarbon spacer groups can also be further substituted by substituents well known in the art, such as C₁₋₆alkyl, phenyl, C₁₋₆haloalkyl, hydroxy, C₁₋₆alkoxy, C₁₋₆alkoxyalkyl, C₁₋₆alkoxyC₁₋₆alkoxy, aryloxy, keto, C₂₋₆alkoxycarbonyl, C₂₋₆alkoxycarbonylC₁₋₆alkyl, C₂₋₆alkylcarbonyloxy, arylcarbonyloxy, arylcarbonyl, amino, mono- or di-(C₁₋₆)alkylamino, or any other suitable substituents known in the art.

Thus, a SAM-forming molecular species generally comprises a species having the generalized structure R′-A-R″, where R′ is selected to bind to a particular surface of material, A is a spacer, and R″ is a group that is exposed when the species forms a SAM. Also, the molecular species may comprises a species having the generalized structure R″-A′-R′-A-R″, where A′ is a second spacer or the same as A, or R′″-A′-R′-A-R″, where R′″ is the same or different exposed functionality as R″.

Suitably, therefore, a SAM-forming molecular species can be selected from sulfur-containing molecules, such as alkyl or aryl thiols, disulfides, dithiolanes or the like, carboxylic acids, sulfonic acids, phosphonic acids, hydroxamic acids or the like, or other reactive compounds, such as silly halides or the like.

A particular class of molecules suitable for use as a SAM-forming molecular species for use with a silver alloy coated substrate include thiols, in particular an alkanethiol, such as H—(CH₂)ₙ—SH, where n=16 to 20, in particular octadecanethiol.

SAMs provided according to the present invention can be formed by suitable techniques known in the art, for example by adsorption from solution, or from a gas phase, or may be applied by use of a stamping step employing a flat unstructured stamp or may be applied by a microcontact printing technique which is generally preferred for use in accordance with the present invention. Preferably, a patterned stamp defining a required pattern is loaded with an ink comprising the SAM-forming molecular species and is brought into contact with the surface of the substrate to be patterned, with the patterned stamp being arranged to deliver the ink to the contacted areas of the surface of said substrate.

Typically, a stamp employed in a method according to the present invention includes at least one indentation, or relief pattern, contiguous with a stamping surface defining a first stamping pattern. The stamp can be formed from a polymeric material. Polymeric materials suitable for use in fabrication of a stamp include linear or branched backbones, and may be crosslinked or noncrosslinked, depending on the particular polymer and the degree of formability desired of the stamp. A variety of elastomeric polymeric materials are suitable for such fabrication, especially polymers of the general class of silicone polymers, epoxy polymers and acrylate polymers. Examples of silicone elastomers suitable for use as a stamp include the chlorosilanes. A particularly preferred silicone elastomer is polydimethylsiloxane (PDMS).

Generally, a SAM-forming molecular species is dissolved in a solvent for transfer to a stamping surface. The concentration of the molecular species in such a solvent for transfer should be selected to be low enough that the species is well-absorbed into the stamping surface, and high enough that a well-defined SAM may be transferred to a material surface without blurring. Typically, the species will be transferred to a stamping surface in a solvent at a concentration of less than 100 mM, preferably from about 0.5 to about 20.0 mM, and more preferably from about 1.0 to about 10.0 mM. Any solvent within which the molecular species dissolves, and which may be carried (e.g. absorbed) by the stamping surface, is suitable. In such selection, if a stamping surface is relatively polar, a relatively polar and/or protic solvent may be advantageously chosen. If a stamping surface is relatively nonpolar, a relatively nonpolar solvent may be advantageously chosen. For example, toluene, ethanol, THF, acetone, isooctane, hexane, cyclohexane, diethyl ether, and the like may be employed. When a siloxane polymer, such as polydimethyl siloxane elastomer (PDMS) as referred to above, is selected for fabrication of a stamp, and in particular a stamping surface, toluene, ethanol, hexane, cyclohexane, decalin, and THF are preferred solvents. The use of such an organic solvent generally aids in the absorption of SAM-forming molecular species by a stamping surface. When the molecular species is transferred to the stamping surface, either near or in a solvent, the stamping surface should be dried before the stamping process is carried out. If a stamping surface is not dry when the SAM is stamped onto the material surface, blurring of the SAM can result. The stamping surface may be air dried, blow dried, or dried in any other convenient manner. The drying manner should simply be selected so as not to degrade the SAM-forming molecular species.

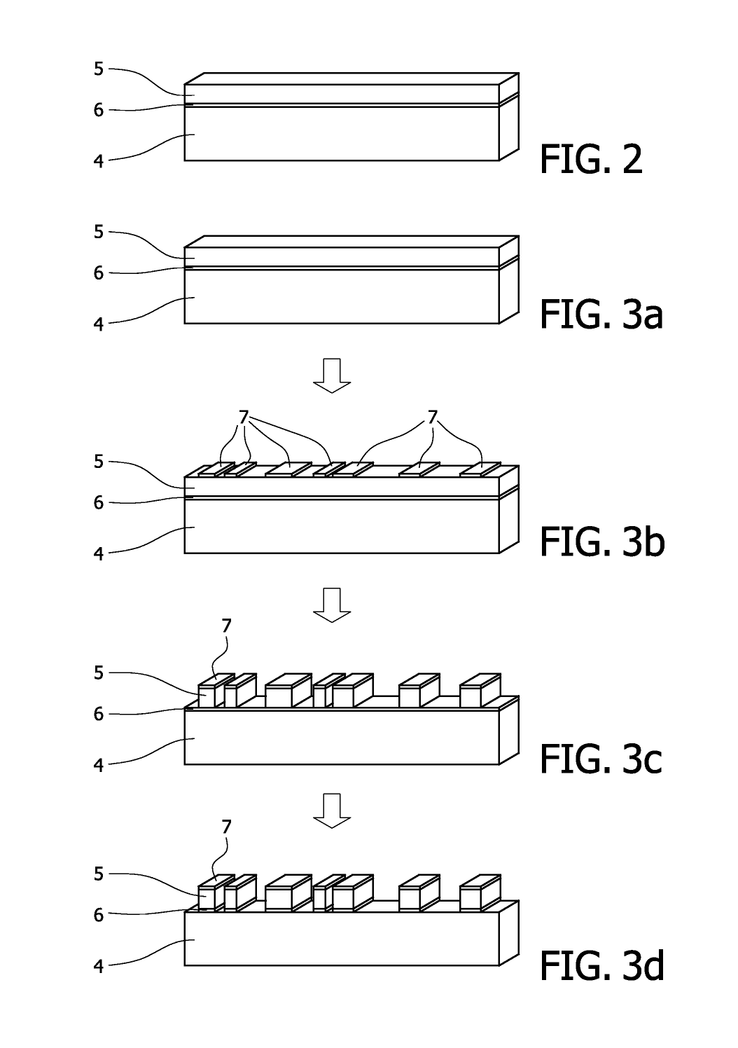

With reference to preferred specific embodiments of the present invention, etching of microcontact printed APC/Mo(Cr) substrates is illustrated in FIG. 2. FIG. 3 shows the principle steps of a multi-step etching process and it is important to appreciate that the provision of a process which allows multi-layer etching using a single etchant solution as is now provided by the present invention provides significant advantage over the prior art processes.

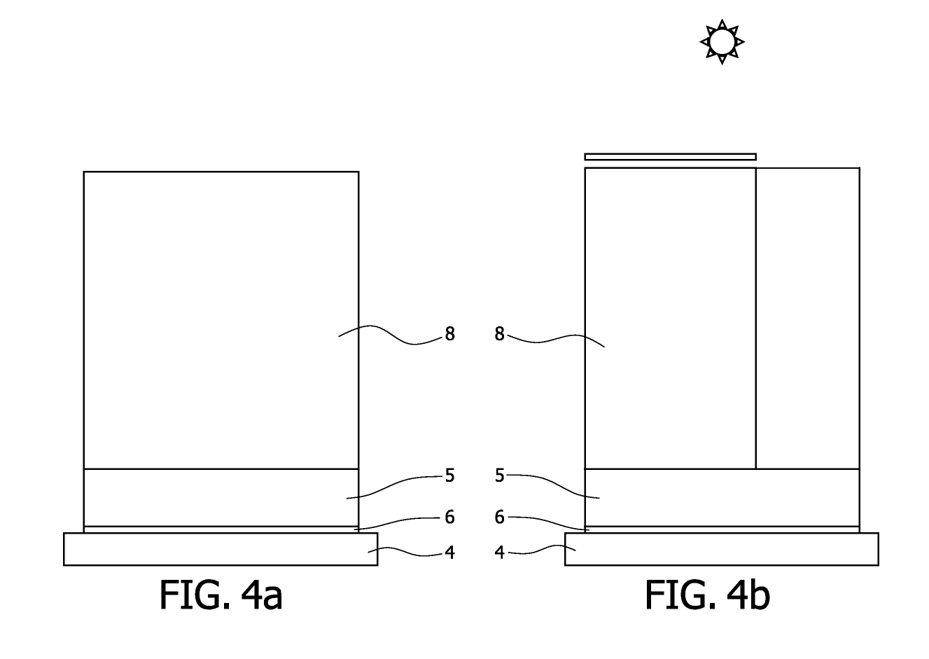

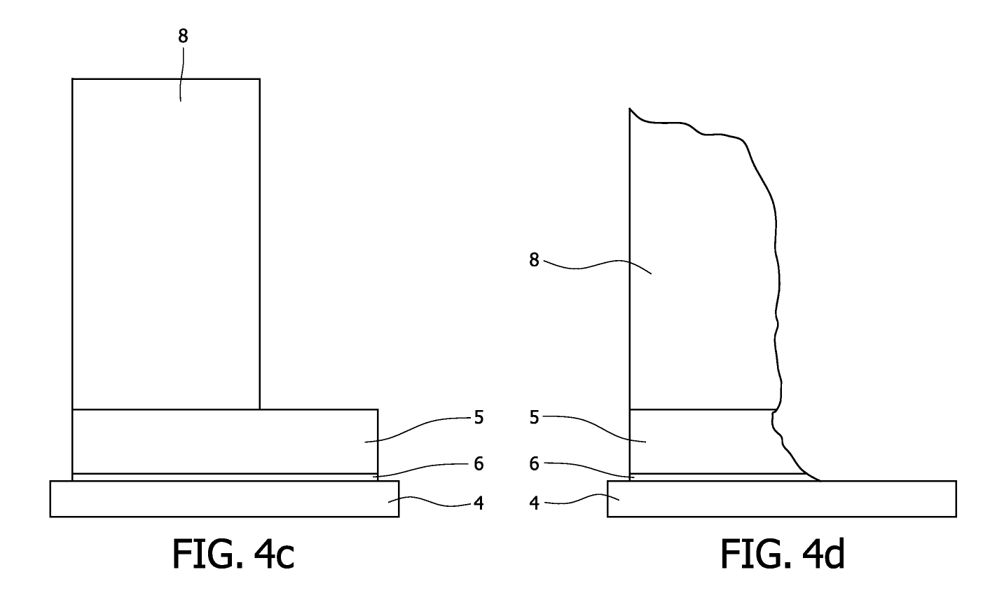

There is an important difference between the requirements of an etch resist for photolithography and an etch resist for soft lithography, with respect to the stability against the etching solution. Photolithographic etch resists are usually applied with a thickness of up to 1000 nanometers as shown in FIG. 4. After photo patterning (b) and selective removal of the resist (c), a relatively thick resist layer is protecting the underlying metal from the etching solution. In a worse case scenario the resist may be etched away by the etchant solution at the same rate as the metal layer(s) and still a reasonable result would be obtained, as shown for the 220 nm APC/Mo(Cr) layers in FIG. 4d.

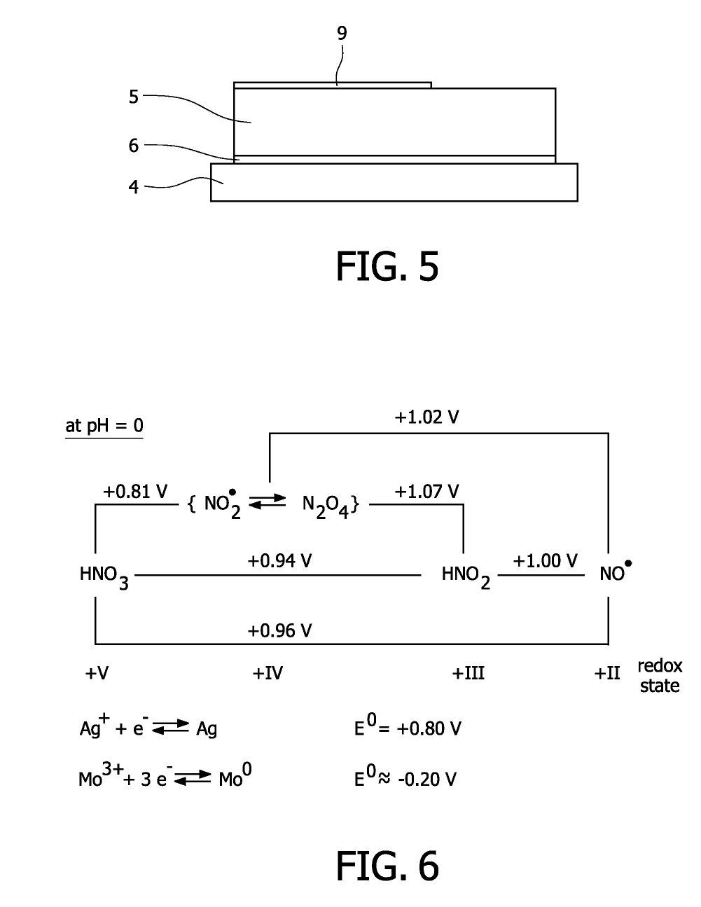

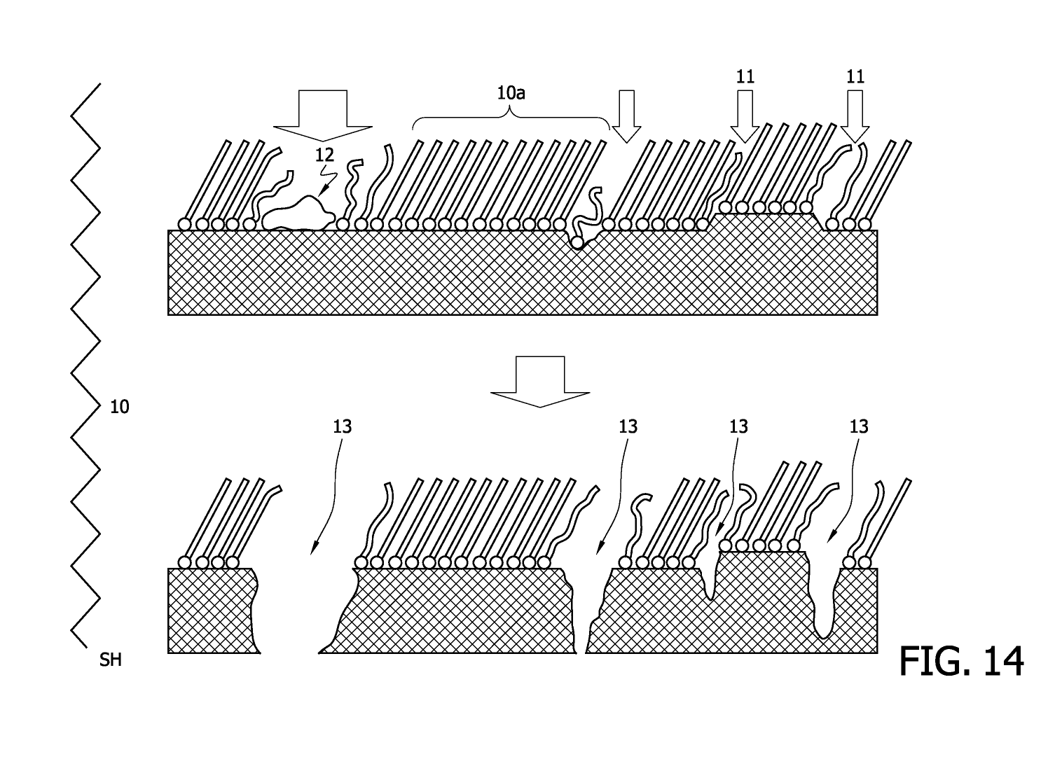

Inspection of FIG. 5 reveals that a low stability of a SAM resist against an etching solution cannot be tolerated and would not provide a useful etching process. The development of an etching solution for a μCP process is thus significantly more demanding, but has now been achieved by the present invention. Basically, no attack on the SAM can be accepted at all because it would otherwise translate directly to defects like pinholes in the final substrate as shown in FIG. 14.

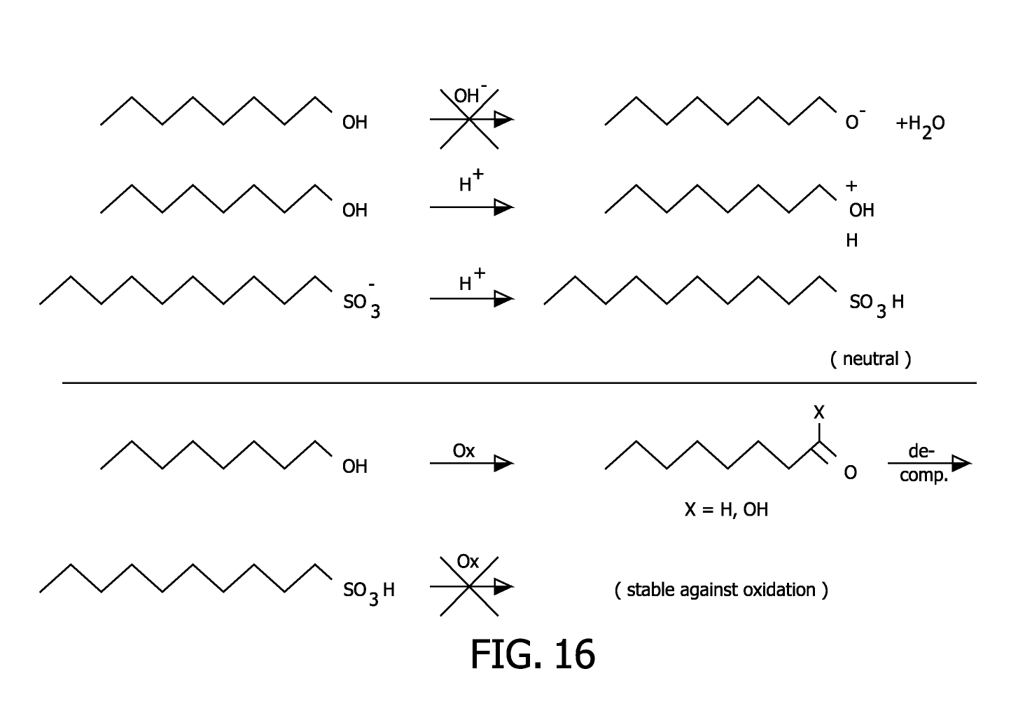

It has also been found that in accordance with certain embodiments of the present invention the quality of the developed pattern can be further improved significantly by choosing suitable additives for an etching solution. With reference to the above discussed prior art, the use of 1-octanol as a possible additive to the etching bath comprising nitric acid, trifluoroacetic acid (TFA), water and a nitrite salt, substantially as hereinbefore described, and etching baths comprising nitric acid, phosphoric acid, acetic acid, water and nitrites in various amounts, showed no improvement in the etching performance in these systems was observed. A possible reason for this might be that alkyl alcohols, such as 1-octanol, are subject to protonation in strongly acidic media, as described in following equation (16) and further illustrated in FIG. 16:

CH₃(CH₂)₇OH+H⁺ [symbol] [CH₃(CH₂)₇OH₂]⁺ (16)

Such positively charged, protonated alcohol molecules experience repulsive Coulomb interactions, when forced together in a densely packed assembly or monolayer. Consequently the tendency to densely fill in defects in an alkanethiol SAM as illustrated in FIG. 15 is being reduced dramatically.

Furthermore, alkyl alcohols are subject to oxidation in nitric acid or nitrate containing acidic solutions, by which they are converted to aldehydes (RCHO) or carboxylic acids (RCOOH) as shown in equation (17) or they even undergo unselective oxidative decomposition (J. March, Advanced Organic Chemistry. 1992, John Wiley & Sons: New York. P 1167-71).

RCH₂OH—[HNO₃]→RCHO—[HNO₃]—RCOOH (17)

The above discussed prior art use of SDS (sodium dodecyl sulphate) is not a good alternative, since as a sulfuric acid ester it is not stable enough under the strongly acidic conditions of the etching bath and is thus subject to hydrolytic ester cleavage.

In accordance with the present invention, we have now found that suitable additives for SAM stabilization are sulfonic and/or phosphonic acids, or salts thereof, bearing an organic group, preferably a hydrophobic alkyl or aryl group. Those additives are useful in combination with all acidic etchant or etching solutions for the development of microcontact printed substrates, and in particular with an etchant solution as provided by the present invention substantially as hereinbefore described. In particular, alkanesulfonic acids are excellent additives in such strongly acidic etching solutions. Using n-alkanesulfonic acids in the concentration range 10⁻⁵ to 10⁻¹M, preferably 10⁻⁴ to 10⁻²M, significantly reduces the number of pinholes formed in an etching process, such as hereinbefore described for APC/Mo(Cr) samples, when etched with an etchant solution comprising nitric acid, trifluoroacetic acid, water and a nitrite salt.

As strong acids, alkanesulfonic acids are to a large degree deprotonated in alkaline, neutral or moderately acidic solutions.

CH₃(CH₂)ₙSO₃H [symbol] CH₃(CH₂)ₙSO₃⁻+H⁺ (18)

The dissociation equilibrium reverts to the left hand side only in strongly acidic media, such as an etchant solution substantially as hereinbefore described. Thus in a strongly acid solution the molecule exists mainly in the neutral protonated form, which does not suffer from Coulomb repulsion between the molecules when aggregated on top of or in defects of a hydrophobic SAM (FIG. 16).

Furthermore, sulfonic acids are much more stable against oxidation or decomposition than any of the above discussed additives (again FIG. 16).

We have observed the most dramatic reduction in etching defects in a process according to the present invention on an ODT SAM resist with alkanesulfonic acids H—(CH₂)ₙSO₃H and alkali metal salts (especially sodium salts) thereof, in which n=8-12. For shorter alkyl chain lengths the number of pinholes was reduced less significantly. Longer alkyl chains, on the other hand, resulted in impractical long etching times and in cases of very long chains even solubility problems of the sulfonic acids in water.

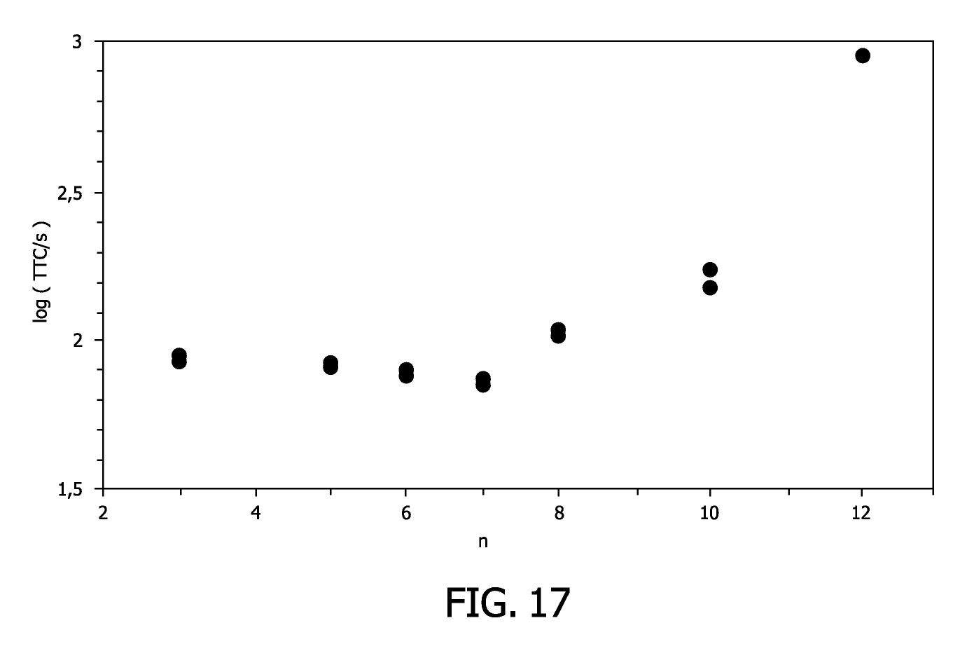

FIG. 17 shows the dependence of the etching time required to completely etch away both metal layers of the described substrates (time to clear, TTC) on the carbon chain length “n” of the added alkanesulfonic acid (H—(CH₂)ₙSO₃H). The concentration of sulfonic acid additive (or a metal salt thereof) was 10⁻³M throughout the series. The quality of the pattern obtained after etching increased steadily for a substrate etched in a bath containing sulfonic acids with n>7. The best etch quality (lowest defect density) was obtained with the acids with n=10, 11 and 12, and a preferred acid is decanesulfonic acid preferably employed as an alkali metal salt thereof, in particular sodium decanesulfonate. As can be seen from FIG. 17, the TTC significantly increases rapidly for n>7. Thus there is a correlation between the increase in the TTC and the chain length of the sulfonic acid where n>7. We ascribe this correlation to the adsorption of the sulfonic acid molecules on the unprotected areas of the substrate surface. The so formed additional monolayer yields some etch protection that causes the additional etching time. On the other hand longer chain sulfonic acids do provide a better defect healing effect, which results in a more stable SAM that translates in a good sample quality even after increased etching times.

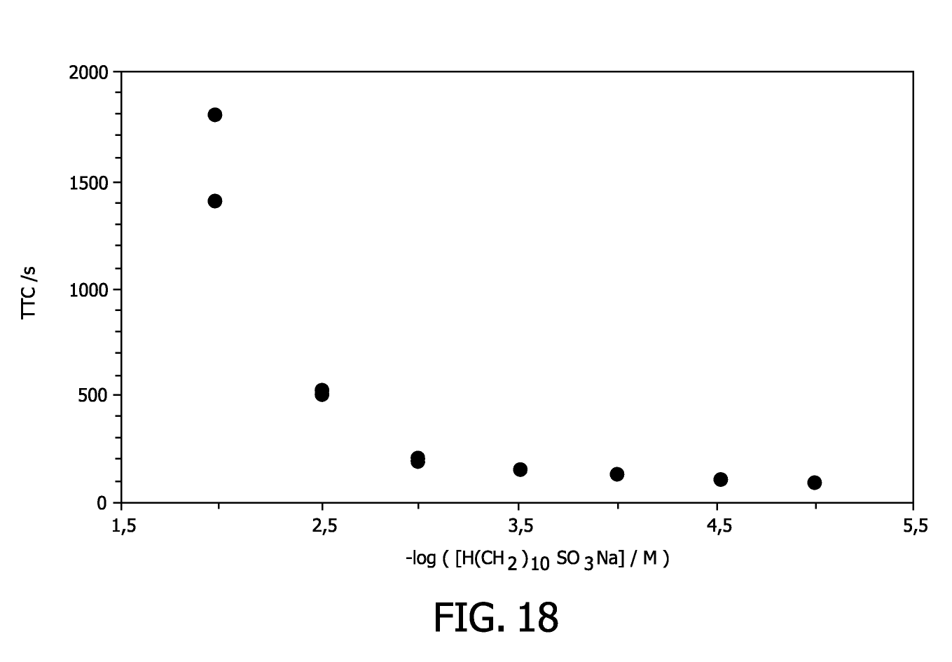

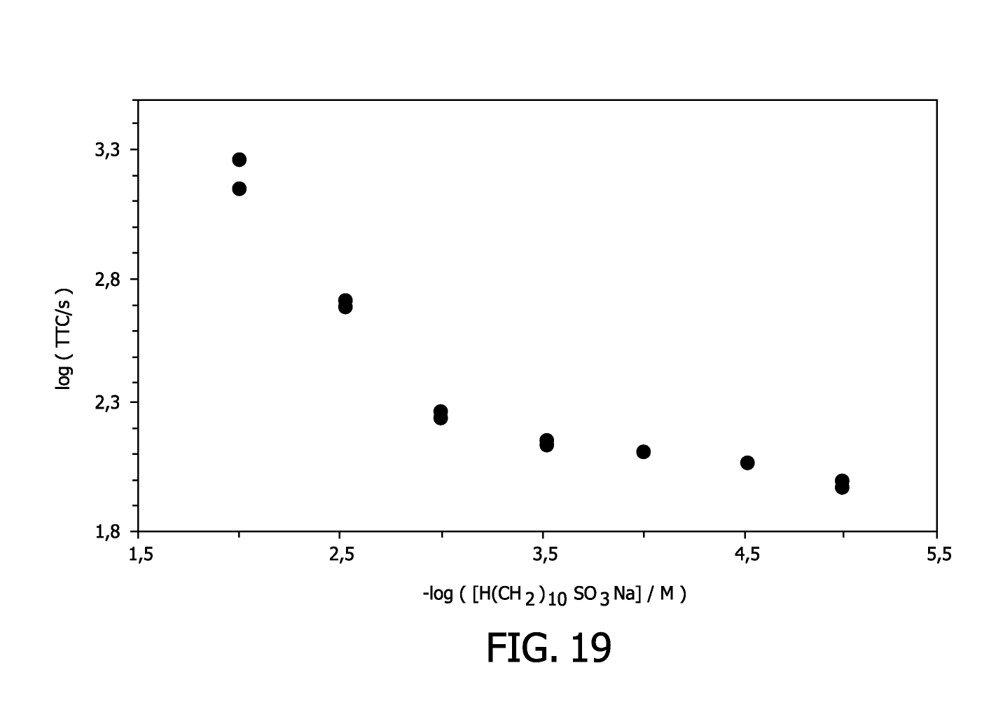

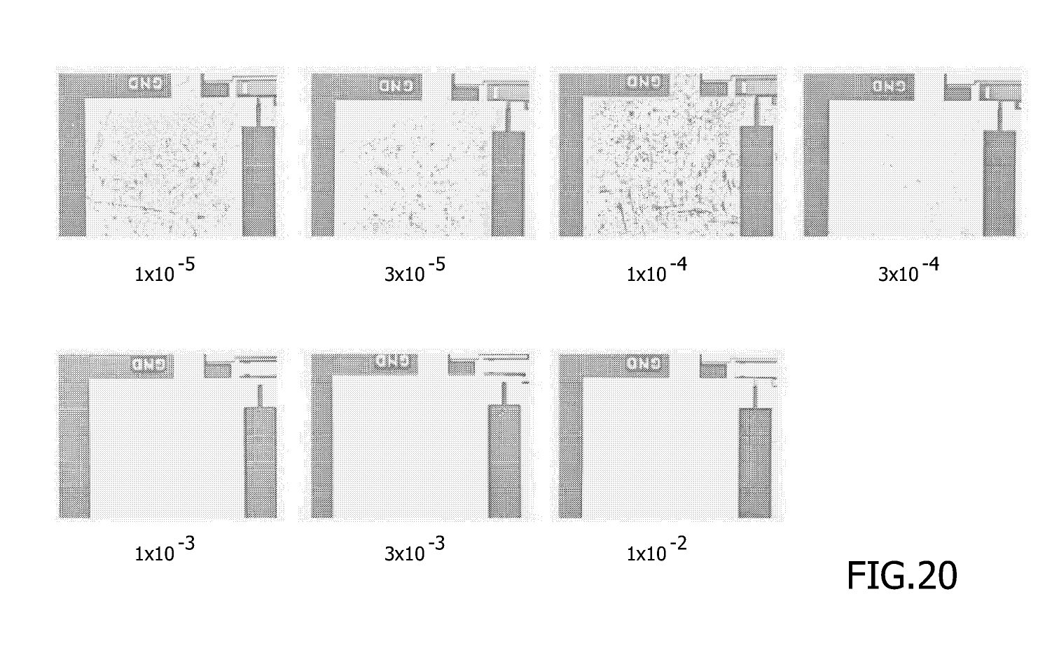

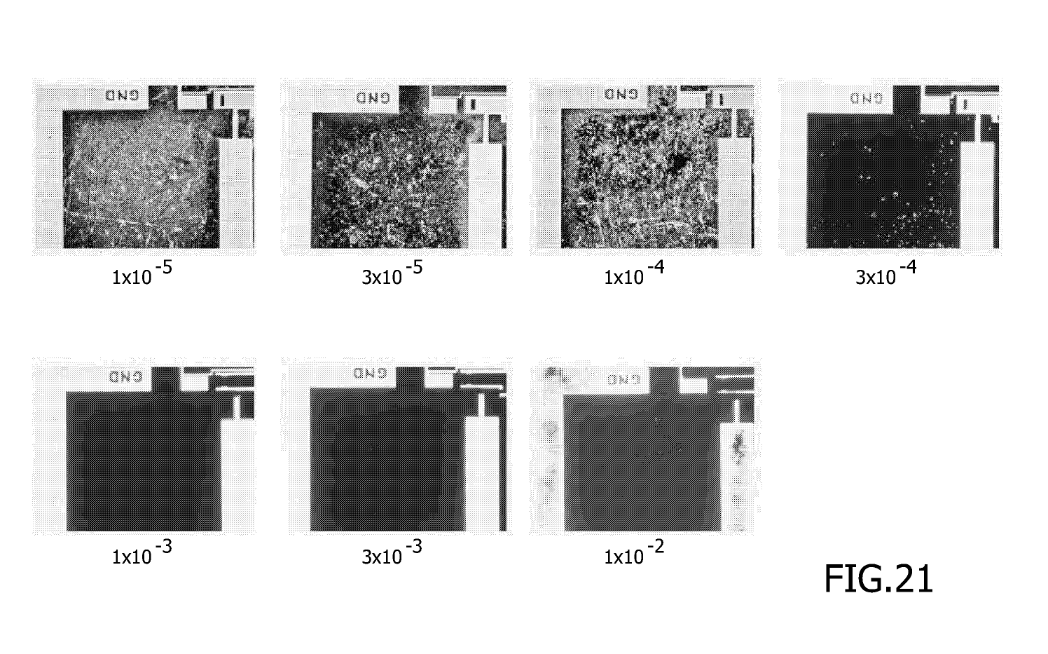

FIG. 18 shows the dependence of the TTC on the concentration of the alkanesulfonate additive, namely sodium decanesulfonate (H(CH₂)₁₀SO₃Na). The TTC increases dramatically for concentrations exceeding 10⁻³M, making the etching process impracticably slow. This more pronounced influence of the concentration on the TTC above about 10⁻³M can more clearly be seen in FIG. 19, which shows a double logarithmic plot of the same set of data. FIGS. 20 and 21 show the corresponding quality of the etched samples in microscope photographs taken under reflective and transmittive illumination respectively. The Figures clearly show that the number of defects decreases dramatically at decanesulfonate concentrations above 3×10⁻⁴M. It can further be seen that the etch quality does not improve significantly for concentrations higher than 10⁻³M.

Considering the very low defect density and the still very low TTC it can thus be concluded that decanesulfonic acid at a concentration of 10⁻³M is a good compromise between an improved etch quality and a practically reasonable etching time in this particular case. For other samples or etching baths, different solutions may be preferred.

The effect of an increasing etching time may be compensated for by changing the concentration of other components of the etching bath, such as nitric acid, TFA or preferably nitrite. We have found that for the listed alternative measures to compensate for the reduced etching rate, the increase of nitrite concentration resulted in the best reproducible results, possibly because varying the concentration of this component does not significantly change the physical properties of the etching bath, such as its viscosity.

Preliminary experiments have shown that the SAM stabilizing effect is not limited to sulfonic acids on the one hand and to aliphatic alkyl chains on the other hand. In experiments in which we patterned a SAM of a polyaromatic thiol as the etch resist on silver and benzenephosphonic acid as the additive in the above described etching solution comprising nitric acid, TFA, water and a nitrite salt, we found a similar decrease in pinhole density when compared to the analogous etching solution containing no benzenephosphonic acid.

Thus we have found that in strongly acidic etching solutions, such as those based on nitric acid, the addition of alkyl- or arylsulfonic acids or alkyl- or arylphosphonic acids or salts thereof in low concentrations (10⁻⁵-10⁻¹M, preferably 10⁻⁴-10⁻²M) dramatically reduces the number of pinholes in the etched substrate, if such a substrate is patterned with a SAM deposited by, for example μCP, and the SAM is composed of molecules with a head group for binding to the substrate and sufficiently long hydrophobic alkyl or aryl tail groups. This effect is probably based on a SAM healing or SAM sealing effect as described above.

The proposed solution has important advantages compared to known additives such as alkanols or SDS. Those known compounds do not show the desired effect in strongly acidic media possibly due to protonation or decomposition issues, whereas the herein proposed molecules work excellently in those media. The herein proposed molecules are furthermore stable in strongly oxidizing and strongly acidic solutions.

As hereinbefore described the preparation procedure of an etching solution is also important for the final etching performance. More specifically, a process of preparing an etchant solution substantially as hereinbefore described comprises:
(a) mixing, under cooling, a halogenated organic acid represented by the formula C(H)ₙ(Hal)ₘ[C(H)ₒ(Hal)ₚ]_{q}CO₂H, where Hal represents bromo, chloro, fluoro or iodo, where:

n is 0, 1, 2 or 3, and m is 0, 1, 2 or 3, with the proviso that m+n=3;

o is 0 or 1, p is 1 or 2, with the proviso that o+p=2;

q is 0 or 1, with the proviso that q+m=1, 2, 3 or 4;

and a selected amount of water (typically at least half of the water to be employed, and more preferably about two thirds of the water to be employed);
(b) adding nitric acid to a mixture obtained further to step (a) to obtain an acid-water mixture;
(c) mixing a nitrite salt and the remaining amount of water; and
(d) adding, under cooling, a solution obtained further to step (c), to the acid-water mixture obtained further to step (b), so as to thus provide an etchant solution in accordance with the present invention.

It is further preferred that the process further comprises step (e), wherein a SAM stabilizing additive typically as described herein should be added to the cooled (to room temperature or below) etchant solution obtained further to step (d).

As hereinbefore explained, addition of the nitrite salt is a key step. Large amounts of nitrogen oxides will be released to the gas phase above the solution if the mixture has not been cooled down to room temperature, or more preferably below room temperature, before the addition of the nitrite solution obtained further to step (c). Prior to the addition of nitrite, it is important that sufficient water has been added to the acid mixture to release most of the hydrolysis energy. The nitrite should also not be added as a solid to the acid-water mixture to avoid locally high concentrations of nitrite. Following these guidelines for the preparation of the etchant solution, good reproducible results are obtained in accordance with the present invention.

There is further provided by the present invention a patterned substrate obtained by a process substantially as hereinbefore described.

There is also provided by the present invention a process of manufacturing an electronic device which includes a substrate provided with patterned material substantially as hereinbefore described, which patterned substrate is prepared by a process according to the present invention. Electronic devices suitably prepared by the present invention include driver electronics of display devices, and organic electronic devices in general. More specifically, a process according to the present invention can provide electronic devices that include organic electronic circuits, and such devices can be selected from the group consisting of LCD, small molecule LEDs, polymer LEDs, electrophoretic (E-ink type) displays, plastic RF (radio frequency) tags and biosensors.

The present invention will now be further illustrated by the following Figures and Examples, which do not limit the scope of the invention in any way.

FIG. 1 is a schematic illustration of the main steps in a method of microcontact printing. More specifically, the four key steps of a microcontact process are reproduction of a stamp (1) with the desired pattern, loading of stamp (1) with an appropriate ink solution; printing with the inked and dried stamp to transfer the pattern from stamp (1) to a substrate surface (2); and development (fixation) of the pattern (3) by means of chemical or electrochemical processes.

FIG. 2 shows a glass substrate (4) bearing two layers of metal which can be etched in accordance with the present invention. More specifically, FIG. 2 shows a glass substrate (4) bearing two layers of metal (5,6), which may represent an APC silver alloy layer (5) (thickness ˜200 nm, APC: Ag (98.1%), Pd (0.9%), Cu (1.0%)) on top of a molybdenum-chromium (Mo(Cr)) adhesion layer (6) (thickness ˜20 nm, MoCr: Mo (97%), Cr (3%)).

FIGS. 3a-3d show the principle steps of a multi-step etching process (steps (a) to (d)). More specifically, FIG. 3a shows the provision of a glass substrate (4) provided with an APC silver alloy layer (5) on top of a molybdenum-chromium (Mo(Cr)) adhesion layer (6) as also illustrated in FIG. 2; FIG. 3b shows application of an etch resist (7); and FIG. 3c and FIG. 3d show selective etching of metal layers (5) and (6) respectively.

FIG. 4 illustrates etching with a photo-resist, wherein photo-resist (8) (thickness ˜1 μm) is employed with a glass substrate (4) provided with an APC silver alloy layer (5) (thickness ˜200 nm) on top of a molybdenum-chromium (Mo(Cr)) adhesion layer (6) (thickness ˜20 nm).

FIG. 5 illustrates application of a SAM resist, which represents a preferred etch resist for use in a process according to the present invention. More specifically, SAM etch resist (9) (thickness ˜3 nm) is applied to APC silver alloy layer (5), on top of a molybdenum-chromium (Mo(Cr)) adhesion layer (6), provided to glass substrate (4).

FIG. 6 provides data from A. F. Holleman and E. Wieberg, Lehrbuch der Anorganischen Chemie. 91-100. Aufl. Ed. 1985, Berlin: Walter de Gruyter), and shows the respective potentials of species present in nitric acid solutions.

FIG. 7 summarizes important equilibria in water based etching solutions.

FIG. 8 shows the decrease of the time to clear (TTC, the time necessary to completely remove all metal layers from the described APC/Mo(Cr) substrates) as a function of the number of substrates etched in an etching bath composed of nitric acid, phosphoric acid and water (H₃PO₄/H₂O/HNO₃ 9:13:3).

FIG. 9 shows an atomic force microscopic picture of a small APC/Mo(Cr) sample (size 1×2 cm²) printed with octadecanethiol and subsequently etched in a solution containing nitric acid, phosphoric acid and water (volume ratio: 3/9/13).

FIG. 10 shows a sample of the same composition as illustrated in FIG. 9 and treated in the same way with the only difference being that the sample size for FIG. 10 was 10×15 cm².

FIG. 11 gives an overview of microscopy photographs of the most often encountered shortcomings in the developed pattern of the microcontact-printed APC/Mo(Cr) substrates, where FIG. 11(a) is a good result, FIG. 11(b) shows pinholes and FIGS. 11(c) and 11(d) show the result of under etching.

FIG. 12 shows the effect of a variation of the nitrite concentration on the time to clear (TTC, the time necessary to completely etch away the APC and the Mo(Cr) layers of the above substrates) in an etching bath of a composition comprising nitric acid, TFA and water (bath composition: 12 vol % HNO₃, 36 vol % TFA, 52 vol % H₂O).

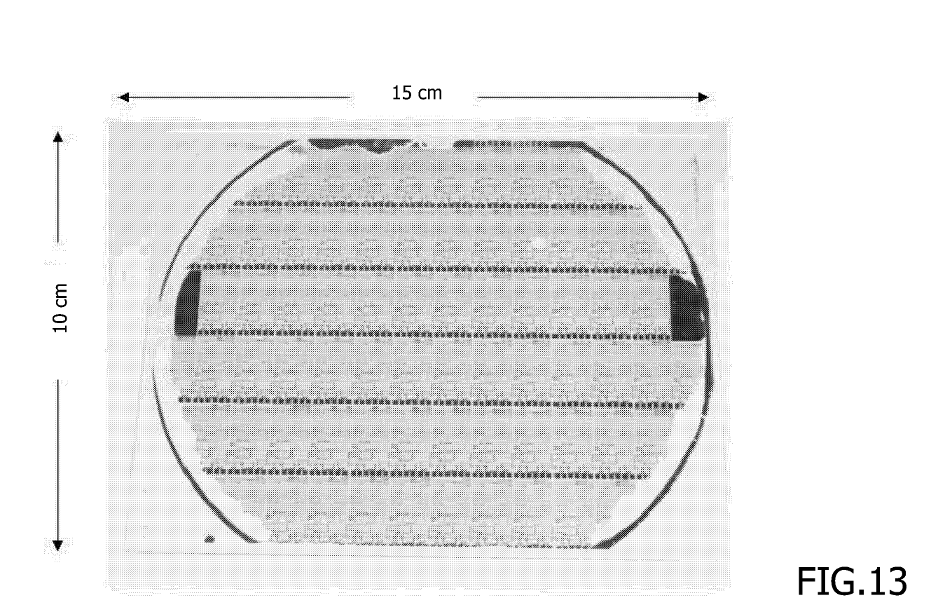

FIG. 13 shows a substrate etched in accordance with the present invention (bath composition: 12 vol % HNO₃, 36 vol % TFA, 52 vol % H₂O, 10⁻³M NaNO₂).

FIG. 14 illustrates defects encountered in printed or solution adsorbed SAM resist layers, in particular an octadecanethiol SAM (10). Only a perfect SAM, on a perfectly flat substrate surface would resemble SAM (10a) in FIG. 14. However, real SAMs are not perfect but have flaws such as molecular defects or domain boundaries. Since real substrates, in particular those prepared by sputtering, are not perfectly flat, these imperfections will also impart the order in the covering SAM (11) as indicated on the right hand side of FIG. 14. Furthermore, even in a clean room environment achieving a perfectly clean substrate surface will always be hampered by dust particles (12), as indicated on the left hand side of FIG. 14, which will again reduce the homogeneity of the SAM resist layer. In the subsequent etching step, such defects will translate to pinholes (13) or larger defects in the etched metal layer (FIG. 14).

FIG. 15 illustrates this “defect-healing” or “defect-sealing” effect of the 1-octanol additive (13) schematically.

FIG. 16 illustrates the differences in protonation and oxidation in acidic and basic etching solutions.

FIG. 17 shows the dependence of the etching time required to completely etch away both metal layers of the described substrates (time to clear, TTC) on the carbon chain length “n” of the added alkanesulfonic acid.

FIG. 18 shows the dependence of the TTC on the concentration of the alkanesulfonate additive, namely sodium decanesulfonate (H(CH₂)₁₀SO₃Na).

FIG. 19 shows a double logarithmic plot of the data of FIG. 18.

FIGS. 20 and 21 show the corresponding quality of the etched samples in microscope photographs taken under reflective and transmittive illumination respectively, at varying molar concentrations of sodium decanesulfonate as shown.

### EXAMPLES

### Example 1

The substrate was a regular glass plate of a size 10×15cm². On top of this a 20 nm thick layer of molybdenum-chromium alloy (97% Mo, 3% Cr) was sputtered followed by a 200 nm thick layer of an APC silver alloy (APC=98.1% Ag, 0.9% Pd, 1.0% Cu). The APC surface was rinsed with water, ethanol and n-heptane and treated with an argon-hydrogen plasma (0.24 mbar Ar, 0.02 mbar H₂, 150 W) for 3 minutes prior to printing. The composition of the plasma gases and the conditions of the plasma treatment were crucial for a good print quality. We have found that the addition of a reducing component, in this case dihydrogen, to the argon plasma can sufficiently remove and prevent the formation of surface oxides in the APC layer. Moderate plasma conditions were also crucial for maintaining a good adhesion between the metal layers and the glass substrate.

A regular poly(dimethylsiloxane) (PDMS) stamp with a glass backplate (Dow Corning AF 45, thickness: 2 mm) with a size of about 10×15 cm² was used. It was inked with the ink solution at least one hour before printing. In this procedure the stamp was immersed in a respective ink solution and stored therein for at least one hour. The ink solution was a clear and colorless 2 millimolar solution of octadecanethiol (Aldrich) in ethanol. Prior to printing the stamp was taken out of the ink solution and thoroughly rinsed with ethanol to remove all excess ink solution and subsequently dried in a stream of nitrogen for about one minute and in the air for another half hour to remove all ethanol from the surface and from the topmost layer of the stamp material.

The so prepared stamp was used for printing the cleaned substrate. Printing was performed with a wave printing machine. Intimate contact over the entire surface was assured by optical inspection. The effective stamp-surface contact time at each position was about 10 seconds.

Subsequently the printed substrates were developed by wet chemical etching at room temperature using an etching bath composed of 60 mL of nitric acid (65% Merck), 180 mL of trifluoroacetic acid (100% Acros), 260 mL of water and 3.45 g of sodium nitrite (97+% Aldrich). Etching was performed by immersing the printed substrates vertically in the indicated etching solution without special precautions and without stirring. The substrate was removed from the etching solution after all the metal was etched away in the not protected regions and a clear pattern was visible. The required etching time was 60 seconds to remove both metal layers and obtain a homogeneous and selectively etched substrate. The etching reaction was quenched by immersing the substrate immediately after removal from the etching solution in a bath containing three liters of water under vigorous stirring. The substrate was then washed with ethanol to remove most of the water and dried in a stream of nitrogen. The printed features were resolved down to below 1 micrometer resolution (line thickness and gaps) in the etching procedure. Thus the monolayer was transferred in the printing step so as to provide a resist, protecting the underlying metal layers in the printed regions, but allowing undisturbed etching in the not printed regions. In FIG. 13 it should be noted that the inhomogeneities at the edges of the substrate are merely due to printing edge effects not due to inhomogeneities in the actual etching step.

### Example 2

A substrate with a top APC layer and a Mo(Cr) adhesion layer as described above was prepared for patterning according to the described procedure. A PDMS stamp was inked and employed for printing as described in Example 1.

Subsequently the printed substrates were developed by wet chemical etching at room temperature using an etching bath composed of 55 mL of nitric acid (65% Merck), 165 mL of trifluoroacetic acid (100% Acros), 260 mL of water and 3.45 g of sodium nitrite (97+% Aldrich). Etching was performed by immersing the printed substrates vertically in the indicated etching solution without special precautions and without stirring. The required etching time was 10 seconds to remove both metal layers and obtain a homogeneous and selectively etched substrate. The printed features were resolved down to below 1 micrometer resolution (line thickness and gaps) in the etching procedure. Thus the monolayer was transferred in the printing step so as to provide a resist, protecting the underlying metal layers in the printed regions but allowing undisturbed etching in the not printed regions. The substrate was removed from the etching solution after all the metal was etched away in the not protected regions and a clear pattern was visible. The etching solution was quenched by immersing the substrate immediately after removal from the etching solution in a three liter bath of water with vigorous stirring. The substrate was then washed with ethanol to remove most of the water and dried in a stream of nitrogen.

### Example 3

The substrate was a regular glass plate of a size 10×15 cm². On top of this a 20 nm thick layer of molybdenum was sputtered followed by a 200 nm thick layer of an APC silver alloy (APC=98.1% Ag, 0.9% Pd, 1.0% Cu). The substrate was treated and cleaned as described in Example 1. It was further printed with an inked PDMS stamp and was etched as described in Example 1. The required etching time was 50 seconds to remove both metal layers and obtain a homogeneous and selectively etched substrate. The etching was quenched in a water bath as described in Example 1. The printed features were resolved down to below 1 micrometer resolution (line thickness and gaps) in the etching procedure.

### Example 4

The substrate was a regular glass plate of a size 10×15 cm². On top of this a 20 nm thick layer of molybdenum-chromium alloy (97% Mo, 3% Cr) was sputtered followed by a 200 nm thick layer of an APC silver alloy (APC=98.1% Ag, 0.9% Pd, 1.0% Cu). The APC surface was rinsed with water, ethanol and n-heptane and treated with an argon-hydrogen plasma (0.24 mbar Ar, 0.02 mbar H₂, 150W) for 3 minutes prior to printing. The composition of the plasma gases and the conditions of the plasma treatment were crucial for a good print quality. We have found that the addition of a reducing component, in this case dihydrogen, to the argon plasma can sufficiently remove and prevent the formation of surface oxides in the APC layer. Moderate plasma conditions were also crucial for maintaining a good adhesion between the metal layers and the glass substrate.

A regular poly(dimethylsiloxane) (PDMS) stamp with a glass backplate (10×15 cm²) was used. It was inked with the ink solution at least one hour before printing. In this procedure the stamp was immersed in a respective ink solution and stored therein for at least one hour. The ink solution was a clear and colorless 2 millimolar solution of octadecanethiol (Aldrich) in ethanol. Prior to printing the stamp was taken out of the ink solution and thoroughly rinsed with ethanol to remove all excess ink solution and subsequently dried in a stream of nitrogen for about one minute and in the air for another half hour to remove all ethanol from the surface and from the topmost layer of the stamp material.

The so prepared stamp was used for printing the cleaned substrate. Printing was performed with a wave printing machine. Intimate contact over the entire surface was assured by optical inspection. The effective stamp-surface contact time at each position was about 20 seconds.

Subsequently the printed substrates were developed by wet chemical etching at room temperature using an etching bath composed of 60 mL of nitric acid (65% Merck), 180 mL of trifluoroacetic acid (100% Acros), 260 mL of water, 3.45 g of sodium nitrite (97+% Aldrich) and 0.10 g of sodium 1-decanesulfonate (98% Acros Organics). Etching was performed by immersing the printed substrates vertically in the indicated etching solution without special precautions and without stirring. The substrate was removed from the etching solution after all the metal was etched away in the not protected regions and a clear pattern was visible. The required etching time was about 100 seconds to remove both metal layers and obtain a homogeneous and selectively etched substrate. The etching reaction was quenched by immersing the substrate immediately after removal from the etching solution in a bath containing three liters of water under vigorous stirring. The substrate was then washed with ethanol to remove most of the water and dried in a stream of nitrogen. The printed features were resolved down to below 1 micrometer resolution (line thickness and gaps) in the etching procedure. Thus the monolayer was transferred in the printing step so as to provide a resist, protecting the underlying metal layers in the printed regions, but allowing undisturbed etching in the not printed regions.

### Example 5

A substrate with a top APC layer and a Mo(Cr) adhesion layer as described above was prepared for patterning according to the described procedure. A PDMS stamp was inked and employed for printing as described in Example 4.

Subsequently the printed substrates were developed by wet chemical etching at room temperature using an etching bath composed of 55 mL of nitric acid (65% Merck), 165 mL of trifluoroacetic acid (100% Acros), 260 mL of water, 3.45 g of sodium nitrite (97+% Aldrich) and 0.10 g of sodium 1-decanesulfonate (98% Acros Organics). Etching was performed by immersing the printed substrates vertically in the indicated etching solution without special precautions and without stirring. The required etching time was 130 seconds to remove both metal layers and obtain a homogeneous and selectively etched substrate. The printed features were resolved down to below 1 micrometer resolution (line thickness and gaps) in the etching procedure. Thus the monolayer was transferred in the printing step so as to provide a resist, protecting the underlying metal layers in the printed regions but allowing undisturbed etching in the not printed regions. The substrate was removed from the etching solution after all the metal was etched away in the not protected regions and a clear pattern was visible. The etching solution was quenched by immersing the substrate immediately after removal from the etching solution in a three liter bath of water with vigorous stirring. The substrate was then washed with ethanol to remove most of the water and dried in a stream of nitrogen.

### Example 6

The substrate was a regular glass plate of a size 10×15 cm². On top of this a 20 nm thick layer of molybdenum was sputtered followed by a 200 nm thick layer of an APC silver alloy (APC=98.1% Ag, 0.9% Pd, 1.0% Cu). The substrate was treated and cleaned as described in Example 4. It was further printed with an inked PDMS stamp and was etched as described in Example 4. The required etching time was 80 seconds to remove both metal layers and obtain a homogeneous and selectively etched substrate. The etching was quenched in a water bath as described in Example 4. The printed features were resolved down to below 1 micrometer resolution (line thickness and gaps) in the etching procedure.

It should be noted that the above-mentioned embodiments illustrate rather than limit the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa. The invention may be implemented by means of hardware comprising several distinct elements, and by means of a suitably programmed computer. In a device claim enumerating several means, several of these means may be embodied by one and the same item of hardware. The mere fact that certain measures are recited in mutually different dependent claims does not indicate that a combination of these measures cannot be used to advantage.

1. An etchant solution for patterned etching of at least one surface or surface coating of a substrate, which solution comprises nitric acid, a nitrite salt, a halogenated organic acid represented by the formula C(H)ₙ(Hal)ₘ[C(H)ₒ(Hal)ₚ]_{q}CO₂H, where Hal represents bromo, chloro, fluoro or iodo, where:
n is 0, 1, 2 or 3, and m is 0, 1, 2 or 3, with the proviso that m+n=3;
o is 0 or 1, p is 1 or 2, with the proviso that o+p=2;
q is 0 or 1, with the proviso that q+m=1, 2, 3 or 4;
and balance water.

2. A solution according to claim 1, wherein the halogenated organic acid is trifluoroacetic acid.

3. A solution according to claim 1, wherein said nitrite salt is an alkali metal nitrite salt.

4. A solution according to claim 3, wherein said nitrite salt is sodium nitrite.

5. A solution according to claim 1, which further comprises at least one SAM stabilizing additive selected from the group consisting of sulfonic acids, phosphonic acids, and salts thereof.

6. A solution according to claim 5, wherein said SAM stabilizing additive is decanesulfonic acid, or an alkali metal salt of decanesulfonic acid.

7. An etchant solution for patterned etching of at least one surface or surface coating of a substrate, which solution contains at least one SAM stabilizing additive which comprises decanesulfonic acid, or an alkali metal salt of decanesulfonic acid.

8. A solution according to claim 6, in which the alkali metal salt of decanesulfonic acid is sodium decanesulfonate.

9. A process of preparing an etchant solution according to claim 5, which process comprises:
(a) mixing, under cooling, a halogenated organic acid represented by the formula C(H)ₙ(Hal)ₘ[C(H)ₒ(Hal)ₚ]_{q}CO₂H, where Hal represents bromo, chloro, fluoro or iodo, where:
n is 0, 1, 2 or 3, and m is 0, 1, 2 or 3, with the proviso that m+n=3;
o is 0 or 1, p is 1 or 2, with the proviso that o+p=2;
q is 0 or 1, with the proviso that q+m=1, 2, 3 or 4;
and a selected amount of water;
(b) adding nitric acid to a mixture obtained further to step (a) to obtain an acid-water mixture;
(c) mixing a nitrite salt and the remaining amount of water;
(d) adding, under cooling, a solution obtained further to step (c), to the acid-water mixture obtained further to step (b), so as to thus provide an etchant solution for patterned etching of at least one surface or surface coating of a substrate, which solution comprises nitric acid, a nitrite salt, a halogenated organic acid represented by the formula C(H)ₙ(Hal)ₘ[C(H)ₒ(Hal)ₚ]_{q}CO₂H, where Hal represents promo, chloro, fluoro or iodo, where:
n is 0, 1, 2 or 3, and m is 0, 1, 2 or 3, with the proviso that m+n=3;
o is 0 or 1, p is 1 or 2, with the proviso that o=p=2;
q is 0 or 1 with the proviso that q+m=1, 2, 3 or 4;
and balance water; and
(e) where required, adding to the etchant solution obtained further to step (d) at least one SAM stabilizing additive selected from the group consisting of sulfonic acids, phosphonic acids, and salts thereof so as to provide an etchant solution according to claim 5.

10. A process of providing a substrate with a patterned material, which process comprises:
(a) providing a substrate including at least one surface or surface coating to be patterned;
(b) providing an etch resist on said surface or surface coating; and
(c) treating at least said surface or surface coating with an etchant solution according to claim 1, so as to selectively remove surface or surface coating material substantially not underlying said etch resist.

11. A process according to claim 10, wherein step (a) comprises applying to underlying substrate surface at least one adhesion coating comprising molybdenum, titanium, or chromium, or an alloy thereof, followed by application to said adhesion coating a surface coating comprising silver or a silver alloy.

12. A process according to claim 10, wherein said etch resist comprises at least one SAM.

13. A process according to claim 12, wherein said at least one SAM is applied by a microcontact printing technique.

14. A process of manufacturing an electronic device which includes a substrate provided with a patterned material and which patterned substrate is prepared by a process as defined in claim 10.

15. A process according to claim 14, wherein said electronic device is an LCD display.
